(19) United States
(12) Patent Application Publication
(10) Pub. No.: US 2014/0339622 A1
(43) Pub. Date: Nov. 20, 2014

(54) NONVOLATILE SEMICONDUCTOR MEMORY DEVICE AND MANUFACTURING METHOD THEREOF

(71) Applicant: KABUSHIKI KAISHA TOSHIBA, Tokyo (JP)

(72) Inventors: Shotaro MURATA, Aichi (JP); Koichi MATSUNO, Mie (JP); Satoshi NAGASHIMA, Mie (JP)

(73) Assignee: KABUSHIKI KAISHA TOSHIBA, Tokyo (JP)

(21) Appl. No.: 14/152,966

(22) Filed: Jan. 10, 2014

(30) Foreign Application Priority Data
May 14, 2013 (JP) 2013-102304

(51) Int. Cl. H01L 29/423; H01L 27/115

(52) U.S. Cl. CPC H01L 29/4234; H01L 27/1157; H01L 27/11524
USPC 257/316; 438/430

(57) ABSTRACT

A nonvolatile semiconductor memory device includes a semiconductor substrate, a memory cell array having memory cells arranged along a first direction that is transverse to a second direction in which word lines for the memory cells extend, each memory cell including a charge accumulation layer provided over the semiconductor substrate, a control gate electrode provided over the charge accumulation layer, and an inter insulating film provided between the charge accumulation layer and the control gate electrode. The inter insulating film is wider along the first direction than the charge accumulation layer and covers opposing side surfaces of an upper portion of the charge accumulation layer in the first direction. In addition, the control gate electrode may be wider along the first direction than the charge accumulation layer.

### CROSS-REFERENCE TO RELATED APPLICATION

This application is based upon and claims the benefit of priority from Japanese Patent Application No. 2013-102304, filed May 14, 2013, the entire contents of which are incorporated herein by reference.

### FIELD

Embodiments described herein relate generally to a nonvolatile semiconductor memory device and a manufacturing method thereof.

### BACKGROUND

A NAND type flash memory device, which is a type of a nonvolatile semiconductor memory device, includes a memory cell transistor. The memory cell transistor has a control gate electrode. In the related art, there are cases where the control gate electrode is formed using a so-called polycide structure in which metal silicide with high melting point is laminated on polysilicon, or a so-called polymetal structure in which a metal material is laminated on polysilicon.

With miniaturization, it is desirable to prevent operation delays due to an increase in electrical resistance of the control gate electrode and to increase a coupling ratio between the control gate electrode and a charge accumulation layer.

### DESCRIPTION OF THE DRAWINGS

FIG. 1 is a block diagram schematically illustrating an example of an electrical configuration of a NAND type flash memory device according to an embodiment.

FIG. 2 is a plan view schematically illustrating an example of a layout pattern of a part of a memory cell region.

FIGS. 3A and 3B are diagrams schematically illustrating an example of a structure and a manufacturing step of a NAND type flash memory device according to a first embodiment. FIG. 3A is a diagram schematically illustrating an example of a cross-section taken along the line AA of FIG. 2, and FIG. 3B is a diagram schematically illustrating an example of a cross-section taken along the line BB of FIG. 2. This is also the same for FIGS. 5A to 34B.

FIGS. 4A and 4B are partially enlarged views illustrating an example of a memory cell gate electrode according to the embodiment.

FIGS. 5A and 5B are diagrams illustrating an example of a first intermediate step of manufacturing the NAND type flash memory device according to the first embodiment.

FIGS. 6A and 6B are diagrams illustrating an example of a second intermediate step of manufacturing the NAND type flash memory device according to the first embodiment.

FIGS. 7A and 7B are diagrams illustrating an example of a third intermediate step of manufacturing the NAND type flash memory device according to the first embodiment.

FIGS. 8A and 8B are diagrams illustrating an example of a fourth intermediate step of manufacturing the NAND type flash memory device according to the first embodiment.

FIGS. 9A and 9B are diagrams illustrating an example of a fifth intermediate step of manufacturing the NAND type flash memory device according to the first embodiment.

FIGS. 10A and 10B are diagrams illustrating an example of a sixth intermediate step of manufacturing the NAND type flash memory device according to the first embodiment.

FIGS. 11A and 11B are diagrams illustrating an example of a seventh intermediate step of manufacturing the NAND type flash memory device according to the first embodiment.

FIGS. 12A and 12B are diagrams illustrating an example of an eighth intermediate step of manufacturing the NAND type flash memory device according to the first embodiment.

FIGS. 13A and 13B are diagrams illustrating an example of a ninth intermediate step of manufacturing the NAND type flash memory device according to the first embodiment.

FIGS. 14A and 14B are diagrams illustrating an example of a tenth intermediate step of manufacturing the NAND type flash memory device according to the first embodiment.

FIGS. 15A and 15B are diagrams illustrating an example of an eleventh intermediate step of manufacturing the NAND type flash memory device according to the first embodiment.

FIGS. 16A and 16B are diagrams illustrating an example of a twelfth intermediate step of manufacturing the NAND type flash memory device according to the first embodiment.

FIGS. 17A and 17B are diagrams illustrating an example of a thirteenth intermediate step of manufacturing the NAND type flash memory device according to the first embodiment.

FIGS. 18A and 18B are diagrams illustrating an example of a fourteenth intermediate step of manufacturing the NAND type flash memory device according to the first embodiment.

FIGS. 19A and 19B are diagrams illustrating an example of a fifteenth intermediate step of manufacturing the NAND type flash memory device according to the first embodiment.

FIGS. 20A and 20B are diagrams illustrating an example of a sixteenth intermediate step of manufacturing the NAND type flash memory device according to the first embodiment.

FIGS. 21A and 21B are diagrams schematically illustrating an example of a structure and a manufacturing step of a NAND type flash memory device according to a second embodiment.

FIGS. 22A and 22B are diagrams illustrating an example of a first intermediate step of manufacturing the NAND type flash memory device according to the second embodiment.

FIGS. 23A and 23B are diagrams illustrating an example of a second intermediate step of manufacturing the NAND type flash memory device according to the second embodiment.

FIGS. 24A and 24B are diagrams illustrating an example of a third intermediate step of manufacturing the NAND type flash memory device according to the second embodiment.

FIGS. 25A and 25B are diagrams illustrating an example of a fourth intermediate step of manufacturing the NAND type flash memory device according to the second embodiment.

FIGS. 26A and 26B are diagrams illustrating an example of a fifth intermediate step of manufacturing the NAND type flash memory device according to the second embodiment.

FIGS. 27A and 27B are diagrams illustrating an example of a sixth intermediate step of manufacturing the NAND type flash memory device according to the second embodiment.

FIGS. 28A and 28B are diagrams illustrating an example of a seventh intermediate step of manufacturing the NAND type flash memory device according to the second embodiment.

FIGS. 29A and 29B are diagrams illustrating an example of an eighth intermediate step of manufacturing the NAND type flash memory device according to the second embodiment.

FIGS. 30A and 30B are diagrams illustrating an example of a ninth intermediate step of manufacturing the NAND type flash memory device according to the second embodiment.

FIGS. 31A and 31B are diagrams illustrating an example of a tenth intermediate step of manufacturing the NAND type flash memory device according to the second embodiment.

FIGS. 32A and 32B are diagrams illustrating an example of an eleventh intermediate step of manufacturing the NAND type flash memory device according to the second embodiment.

FIGS. 33A and 33B are diagrams illustrating an example of a twelfth intermediate step of manufacturing the NAND type flash memory device according to the second embodiment.

FIGS. 34A and 34B are diagrams illustrating an example of a thirteenth intermediate step of manufacturing the NAND type flash memory device according to the second embodiment.

### DETAILED DESCRIPTION

Embodiments provide a nonvolatile semiconductor memory device capable of improving a coupling ratio between a control gate electrode and a charge accumulation layer by preventing an increase in electrical resistance of the control gate electrode, and a manufacturing method thereof.

In general, according to one embodiment, a nonvolatile semiconductor memory device includes a semiconductor substrate, and a memory cell array having memory cells arranged along a first direction that is transverse to a second direction in which word lines for the memory cells extend, each memory cell including a charge accumulation layer provided over the semiconductor substrate, a control gate electrode provided over the charge accumulation layer, and an inter insulating film provided between the charge accumulation layer and the control gate electrode. The inter insulating film is wider along the first direction than the charge accumulation layer and covers opposing side surfaces of an upper portion of the charge accumulation layer in the first direction. In addition, the control gate electrode may be wider along the first direction than the charge accumulation layer.

### First Embodiment

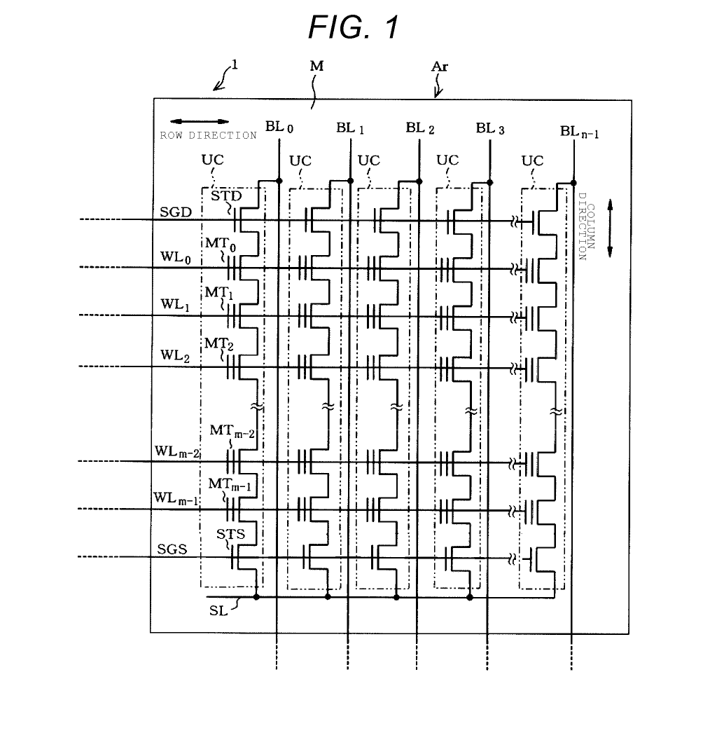

Hereinafter, with reference to FIGS. 1 to 20B, the first embodiment will be described using a NAND type flash memory device as an example of a nonvolatile semiconductor memory device. In the following description, elements having the same function and configuration are given the same reference numeral. The drawings are schematic, and a relationship between the thickness and the planar dimensions, ratios of the thicknesses of respective layers, and the like do not necessarily conform to actual ones. In addition, vertical and horizontal directions indicate relative directions when a surface side of a semiconductor substrate on which a circuit is formed in is defined as a top surface, and do not necessarily conform to directions based on gravity.

FIG. 1 is a block diagram schematically illustrating an example of an electrical configuration of the NAND type flash memory device. As shown in FIG. 1, the NAND type flash memory device 1 includes a memory cell array Ar in which memory cells are disposed in a matrix.

Unit memory cells UC are disposed in the memory cell array Ar of a memory cell region M. In each of the unit memory cells UC, a selection gate transistor STD is provided on a connection side to bit lines BL₀ to BLₙ₋₁, and a selection gate transistor STS is provided on a source line SL side. Between the selection gate transistors STD and STS, m (where m=2^{k}, for example, m=32) memory cell transistors MT₀ to MTₘ₋₁ are connected in series to each other.

The unit memory cells UC form a memory cell block, and a plurality of memory cell blocks form the memory cell array Ar. In other words, a single block is formed by arranging n columns of the unit memory cells UC in parallel in a row direction (the horizontal direction in FIG. 1). The memory cell array Ar is formed by arranging blocks in a column direction (the vertical direction in FIG. 1). In addition, for simplification of description, FIG. 1 shows a single block.

A word line WLₘ₋₁ is connected to a control gate of the m-th memory cell transistor MTₘ₋₁ of each unit memory cells UC. A word line WL₂ is connected to a control gate of the third memory cell transistor MT₂ of each unit memory cells UC. A word line WL₁ is connected to a control gate of the second memory cell transistor MT₁ of each unit memory cells UC. A word line WL₀ is connected to a control gate of the first memory cell transistor MT₀ of each unit memory cells UC. A control line SGS is connected to a gate of the selection gate transistor STS of each unit memory cells UC, and a control line SGD is connected to the selection gate transistor STD of each unit memory cells UC. Each selection gate transistor STS is connected to the source line SL. The selection gate transistors STD are respectively connected to the bit lines BL₀ to BLₙ₋₁. The bit lines BL₀ to BLₙ₋₁ are each connected to a sense amplifier (not shown).

The gate electrodes of the selection gate transistors STD of the unit memory cells UC arranged in the row direction are electrically connected to each other via the control line SGD. Similarly, the gate electrodes of the selection gate transistors STS of the unit memory cells UC arranged in the row direction are electrically connected to each other via the control line SGS. The sources of the selection gate transistors STS are connected in common to the source line SL. The gate electrodes of the memory cell transistors MT₀ to MTₘ₋₁ of the unit memory cells UC arranged in the row direction are electrically connected to each other via the corresponding word lines WL₀ to WLₘ₋₁.

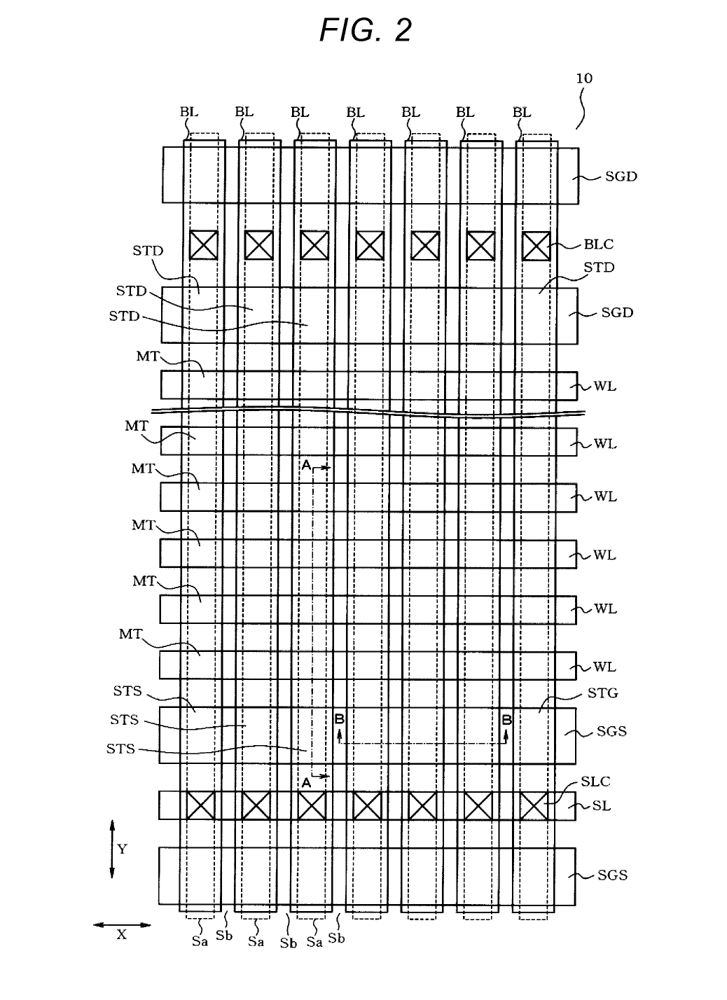

FIG. 2 is a plan view schematically illustrating an example of a layout pattern of a part of the memory cell region M. In addition, hereinafter, the bit lines BL₀ to BLₙ₋₁ are referred to as bit lines BL, the word lines WL₀ to WLₘ₋₁ are referred to as word lines WL, and the memory cell transistors MT₀ to MTₘ₋₁ are referred to as memory cell transistors MT.

In FIG. 2, the source line SL, the control line SGS, the word lines WL, and the control line SGD are spaced from each other in a Y direction (the vertical direction in FIG. 2, and the column direction in FIG. 1), and are disposed in parallel so as to extend in an X direction (the horizontal direction in FIG. 2, and the row direction in FIG. 1). The bit lines BL are spaced from each other with a predetermined gap in the X direction and are disposed in parallel so as to extend in the Y direction.

An element isolation region Sb is formed so as to extend in the Y direction in FIG. 2. The element isolation region Sb has a shallow trench isolation (STI) structure which is formed by embedding an insulating film in a trench. The element isolation region Sb is formed in plurality in the X direction with a predetermined gap. Element regions Sa which are formed so as to extend in the Y direction are formed separately from each other by the element isolation regions Sb in the X direction in a surface layer part of a semiconductor substrate 10. In other words, the element isolation region Sb is provided between the element regions Sa, and the semiconductor substrate 10 is divided into the element regions Sa by the element isolation regions Sb.

The word lines WL are formed so as to extend in the direction (the X direction in FIG. 2) perpendicular to the element regions Sa. The word lines WL are formed with a predetermined distance in the Y direction in FIG. 2. The memory cell transistor MT is disposed at an intersection of the word line WL and the element region Sa. A single memory cell transistor MT forms a nonvolatile memory element. Memory cell transistors MT adjacent in the Y direction form a part of a NAND string (memory cell string).

The selection gate transistors STS and STD are respectively disposed at intersections of the control lines SGS and SGD and the element regions Sa. The selection gate transistors STS and STD are provided so as to be adjacent to both outsides of the memory cell transistors MT located at end parts of the NAND string in the Y direction in FIG. 2.

The selection gate transistors STS on the source line SL side are provided in the X direction in FIG. 2. Selection gate electrodes SG which are gate electrodes of the selection gate transistors STS are electrically connected to each other via the control line SGS. The selection gate transistors STS are formed at the intersections of the control line SGS and the element regions Sa. Source line contacts SLC are formed at the intersections of the source line SL and the bit lines BL.

The selection gate transistors STD are provided in the X direction in FIG. 2. Selection gate electrodes SG which are gate electrodes of the selection gate transistors STD are electrically connected to each other via the control line SGD. The selection gate transistors STD are formed at the intersections of the control line SGD and the element regions Sa. Bit line contacts BLC are formed on the respective element regions Sa between the adjacent selection gate transistors STD.

The above description relates to a basic configuration of the NAND type flash memory device according to the first embodiment.

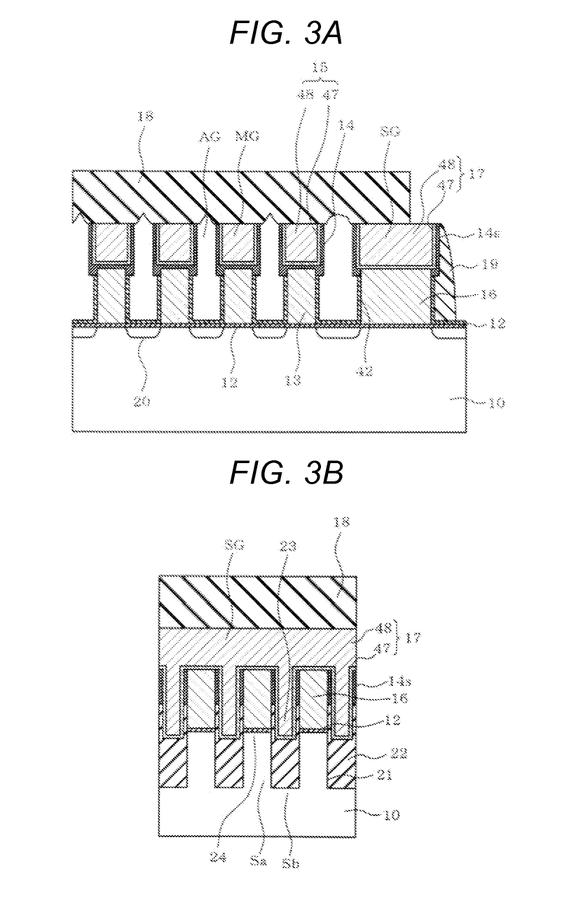

Next, a specific configuration according to the present embodiment will be described with reference to FIGS. 3A to 20B. FIGS. 3A and 3B are diagrams schematically illustrating an example of a structure of the NAND type flash memory device according to the first embodiment. FIG. 3A is a diagram schematically illustrating an example of a cross-section of a portion taken along the line AA of FIG. 2. FIG. 3B is a diagram schematically illustrating an example of a cross-section taken along the line BB of FIG. 2.

In FIG. 3A, memory cell gate electrodes MG and a selection gate electrode SG are provided on the semiconductor substrate 10. The semiconductor substrate 10 may be a silicon substrate of which a conductivity type is, for example, a p type. A gate oxide film 12 is formed on the semiconductor substrate 10. The gate oxide film 12 may be a silicon oxide film which is formed, for example, through thermal oxidization.

The memory cell gate electrode MG is formed by laminating a charge accumulation layer (for example, a floating gate electrode) 13, a first insulating film 14, and a control gate electrode 15 on the gate oxide film 12. The floating gate electrode 13 is made of, for example, polysilicon doped with an impurity. For example, phosphorous may be used as the impurity. The first insulating film 14 may be, for example, an oxide nitride oxide (ONO) film formed of a laminate film of silicon oxide/silicon nitride/silicon oxide. The control gate electrode 15 is formed of a laminate film of a barrier metal 47 made of, for example, tungsten nitride (WN) and a metal film 48 made of, for example, tungsten (W). The first insulating film 14 is formed so as to cover the lower surface and the side surface of the control gate electrode 15. The floating gate electrode 13 and the control gate electrode 15 are insulated from each other by the first insulating film 14.

The selection gate electrode SG is formed by laminating a lower electrode 16 and an upper electrode 17 on the gate oxide film 12. The lower electrode 16 is made of, for example, polysilicon doped with an impurity, and is formed using the same film material as the floating gate electrode 13 used in the memory cell gate electrode MG. For example, phosphorous may be used as the impurity. The upper electrode 17 is formed of, for example, a laminate film of the barrier metal 47 made of tungsten nitride, and the metal film 48 formed of a tungsten film. The upper electrode 17 is formed using the same material as the control gate electrode 15 of the memory cell gate electrode MG. A first insulating film side wall 14s with a side wall shape formed by the first insulating film 14 is formed so as to cover the side surface of the upper electrode 17. The first insulating film side wall 14s with a side wall shape formed by the first insulating film. 14 is formed using the same material as a film material used in the memory cell gate electrode MG, for example, using an ONO film. Since the first insulating film 14 is not interposed between the lower electrode 16 and the upper electrode 17, the two electrodes contact each other.

Air gaps AG are provided between memory cell gate electrodes MG, and between the memory cell gate electrode MG and the selection gate electrode SG. An insulating film 18 is formed so as to cover the memory cell gate electrodes MG, and the central portion of the selection gate electrode SG, thereby forming the air gaps AG. In other words, the insulating film 18 may be said to be formed on the air gaps AG. A side wall insulating film 19 is formed on the side surface of the selection gate electrode SG located on an opposite side to the memory cell gate electrode MG. Source drain regions 20 are provided in the surface of the semiconductor substrate 10 on both sides of each of the memory cell gate electrodes MG and both sides of the selection gate electrode SG.

FIG. 3B shows an example of a cross-section of the selection gate electrode SG in the gate width direction. Although the cross-section of the selection gate electrode SG of the selection gate transistor STS is shown as an example, a cross-section of the selection gate electrode SG of the selection gate transistor STD substantially has the same structure. In FIG. 3B, element isolation grooves 21 are provided with a predetermined width in the surface of the semiconductor substrate 10. An element isolation insulating film 22 is embedded in the element isolation groove 21 so as to form the element isolation region Sb. The element regions Sa are formed so as to be divided into a plurality of regions by the element isolation regions Sb in the horizontal direction in FIG. 3B. A groove 23 which is deeper than the lower surface of the gate oxide film 12 is formed at the central part of the element isolation insulating film 22 in FIG. 3B. Here, the element isolation insulating film 22 may be said to have a concave shape. The gate oxide film 12 is formed on the surface of the semiconductor substrate 10 of the element regions Sa, and the lower electrode 16 is formed on the gate oxide film 12. The element isolation insulating film 22 is provided on the side surface of the lower electrode 16 so as to be substantially in contact with the lower half part thereof, and the first insulating film side wall 14s with a side wall shape formed by the first insulating film 14 is provided so as to be substantially in contact with the upper half part. The upper electrode 17 is formed so as to cover the lower electrode 16, the first insulating film side wall 14s, and the element isolation insulating film 22, and is formed so as to cross in the horizontal direction in FIG. 3B as a whole. A part of the upper electrode 17 is embedded in the groove 23 of the element isolation insulating film 22. In other words, the lower surface of the upper electrode 17 is lower than the lower surface of the gate oxide film 12 in the groove 23. As a result, the upper electrode 17 is opposed to the side wall of the lower electrode 16 via the element isolation insulating film 22 and the first insulating film side wall 14s in the embedded portion of the groove 23.

The depth of the groove 23 provided in the element isolation insulating film 22 reaches further downward than the gate oxide film 12. The lower surface of the upper electrode 17 embedded in the groove 23 reaches further downward than the gate oxide film 12. The upper electrode 17 is disposed so as to be opposed to the side surface around the upper surface of the element region Sa via the element isolation insulating film 22 in the embedded portion inside the groove 23. The element region Sa interposed between the grooves 23 corresponds to a channel part 24 of the selection gate transistor STD or STS having the selection gate electrode SG as a gate electrode. The upper electrodes 17 are disposed with the channel part 24 interposed therebetween in the horizontal direction of FIG. 3B in the embedded portions inside the grooves 23.

The channel parts 24 of the element regions Sa and the element isolation regions Sb are alternately disposed in the cross-section in the gate length direction of the selection gate transistors STD and STS. The lower electrode 16 is disposed on the channel part 24 via the gate oxide film 12. The upper electrodes 17 are disposed so as to be opposed to each other with the channel part 24 interposed therebetween from both sides in both side surfaces of the channel part 24. The lower electrode 16 and the upper electrode 17 are electrically connected to each other. The channel part 24 is contiguous to the lower electrode 16 via the gate oxide film 12 and is contiguous to the upper electrode 17 via the element isolation insulating film. 22. As a result, the upper part and both side surfaces of the channel part 24 are covered by the lower electrode 16 and the upper electrode 17 in a saddle shape or a “U” shape in the gate width direction. In other words, the selection gate transistors STD and STS become a so-called fin type field effect transistor (FET). Accordingly, there is an effect in which switching characteristics of the selection gate transistors STD and STS can be improved, and it is possible to suppress a leakage current (off current).

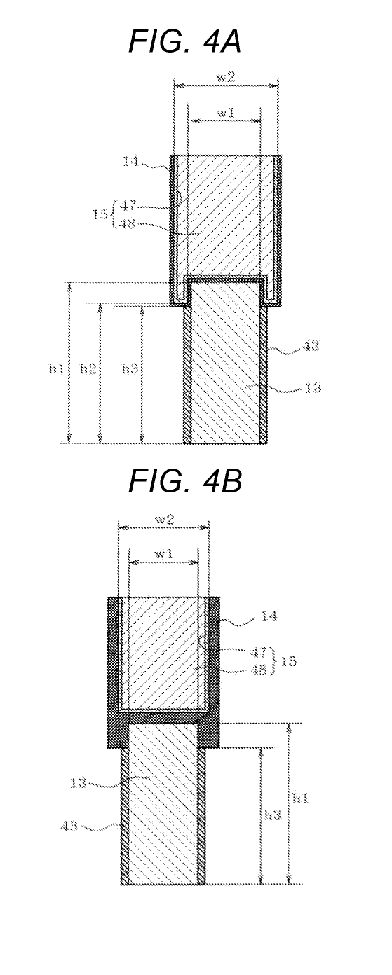

FIGS. 4A and 4B are enlarged views of the memory cell gate electrode portion of FIGS. 3A and 3B. FIGS. 4A and 4B schematically show relative dimensions of and positional relationship among the floating gate electrode 13, the first insulating film 14, and the control gate electrode 15. Two cases are shown in relation to a film thickness of the first insulating film 14. In other words, FIG. 4A shows a case where, at the side surface around the upper surface of the floating gate electrode 13, the floating gate electrode 13 is in contact with the first insulating film 14, and the floating gate electrode 13 is opposed to the control gate electrode 15 with the first insulating film 14 interposed in between. FIG. 4B shows a case where, at the side surface around the upper surface of the floating gate electrode 13, the floating gate electrode 13 is in contact with the first insulating film 14, and the floating gate electrode 13 is not opposed to the control gate electrode 15.

In FIG. 4A, the size w2 (measured in the transverse direction) of the control gate electrode 15 is larger than the size w1 (measured in the transverse direction) of the floating gate electrode 13. In other words, a relationship of w1<w2 holds. In addition, along the gate length direction, the lower end height h2 (measured from the bottom of the floating gate electrode 13) of the part of the control gate electrode 15 that is not located right above the floating gate electrode 13 is smaller than the upper surface height h1 (measured from the bottom of the floating gate electrode 13) of the floating gate electrode 13. In other words, along the gate length direction, the lowermost end of the control gate electrode 15 is lower than the upper surface height of the floating gate electrode 13. Also, along the gate length direction, the lower end height h3 (measured from the bottom of the floating gate electrode 13) of the part of the first insulating film 14 that is not located right above the floating gate electrode 13 is smaller than the upper surface height h1 of the floating gate electrode 13. In other words, along the gate length direction, the lowermost end of the first insulating film 14 is lower than the upper surface height of the floating gate electrode 13. Therefore, in consideration of laminate order, a relationship of h1>h2 and h1>h3 is established. Here, any reference point of h1, h2 and h3 may be set, and, here, the bottom surface of the floating gate electrode 13 is used as a reference. In this case, the upper surface and the side surface around the upper surface of the floating gate electrode 13 are covered by the first insulating film 14.

In FIG. 4A, at the upper surface and the side surface around the upper surface of the floating gate electrode 13, the control gate electrode 15 covers the floating gate electrode 13 in a saddle shape or a “U” shape with the first insulating film 14 interposed in between. In other words, at the upper surface and the side surface around the upper surface of the floating gate electrode 13, the control gate electrode 15 and the floating gate electrode 13 are opposed to each other through the first insulating film 14. At the upper surface and the side surface around the upper surface of the floating gate electrode 13, the floating gate electrode 13 is in contact with the first insulating film 14. Therefore, since the area in which the floating gate electrode 13 is opposed to the control gate electrode 15 through the first insulating film increases, a coupling ratio between the floating gate electrode 13 and the control gate electrode 15 is improved and thus memory writing and erasure characteristics are improved.

In addition, since the size w2 (measured in the transverse direction) of the control gate electrode 15 is larger than the size w1 (measured in the transverse direction) of the floating gate electrode 13, it is possible to reduce a resistance value of the control gate electrode 15, to thereby contribute to a high-speed operation of the memory cell transistor MT.

In FIG. 4B, the size w2 (measured in the transverse direction) of the control gate electrode 15 is larger than the size w1 (measured in the transverse direction) of the floating gate electrode 13. In this case, a relationship of w1<w2 holds. In addition, along the gate length direction, the lower end height h3 (measured from the bottom of the floating gate electrode 13) of the part of the first insulating film 14 that is not located right above the floating gate electrode 13 is smaller than the upper surface height h1 (measured from the bottom of the floating gate electrode 13) of the floating gate electrode 13. Thus, a relationship of h1>h3 holds. In addition, in this case, the upper surface and the side surface around the upper surface of the floating gate electrode 13 are covered by the first insulating film 14. Further, along the gate length direction, the lower end height h2 (measured from the bottom of the floating gate electrode 13) of the part of the control gate electrode 15 that is not located right above the floating gate electrode 13 is set to be larger than the upper surface height h1 of the floating gate electrode 13. As a result, at the upper surface and the side surface around the upper surface of the floating gate electrode 13, the floating gate electrode 13 is in contact with the first insulating film 14, and the control gate electrode 15 is not disposed on the part of the first insulating film 14 that is formed on the side surface of the floating gate electrode 13.

However, the control gate electrode 15 is contiguous to the floating gate electrode 13 through the first insulating film 14 at the upper surface of the floating gate electrode 13 and protrudes in the transverse direction with respect to the floating gate electrode 13 along the gate length direction. Therefore, in relation to the floating gate electrode 13, a strong electric field can be applied to the floating gate electrode 13 from the protruding portion of the control gate electrode 15 through the first insulating film 14 which has a permittivity higher than that of the air gap AG. Accordingly, it is possible to improve a coupling ratio, and thus memory writing and erasure characteristics are improved.

In addition, since the size (measured in the transverse direction) of the control gate electrode 15 is increased, a resistance value of the control gate electrode 15 is reduced, to thereby contribute to a high-speed operation of the memory cell transistor.

Manufacturing Method

Hereinafter, an example of a manufacturing method of the nonvolatile semiconductor memory device will be described. In description of the present embodiment, characterizing portions are mainly described, but generally other steps may be added between respective steps, and each step may be replaced as necessary if the replacement of the step may be practically performed.

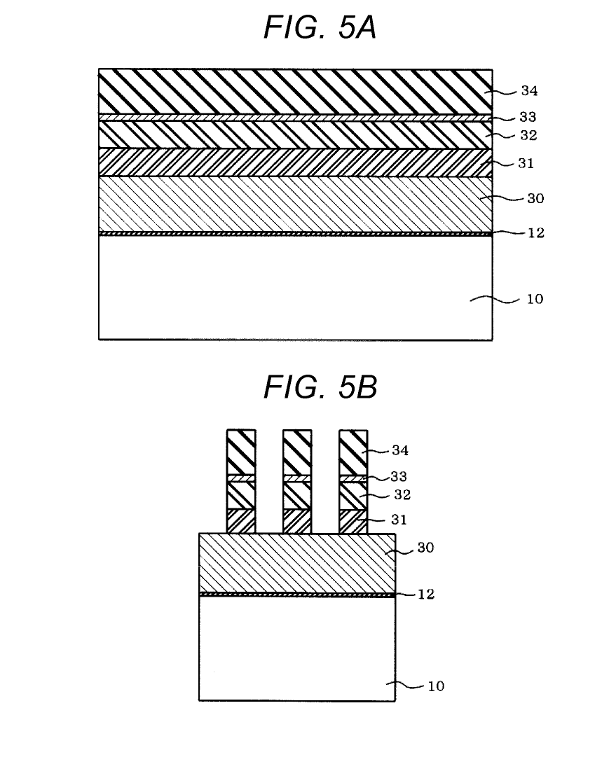

As shown in FIGS. 5A and 5B, a gate oxide film 12, a first polysilicon film 30, a first silicon nitride film 31, a first silicon oxide film 32, and a second polysilicon film 33 are sequentially formed on the semiconductor substrate 10. The semiconductor substrate 10 may be, for example, a p type silicon substrate. The gate oxide film 12 may be formed by thermally oxidizing the surface of the semiconductor substrate 10 at the temperature of 950° C. in a dry O₂ atmosphere. The first polysilicon film 30, the first silicon nitride film 31, the first silicon oxide film 32, and the second polysilicon film 33 may be formed using a chemical vapor deposition (CVD) method. The first polysilicon film 30 is doped with, for example, phosphorous as an impurity.

Next, a resist mask 34 is formed using a lithography method, and is dry-etched in an anisotropic condition using reactive ion etching (RIE). Accordingly, the second polysilicon film 33, the first silicon oxide film 32, and the first silicon nitride film 31 are patterned. Successively, the resist mask 34 is removed.

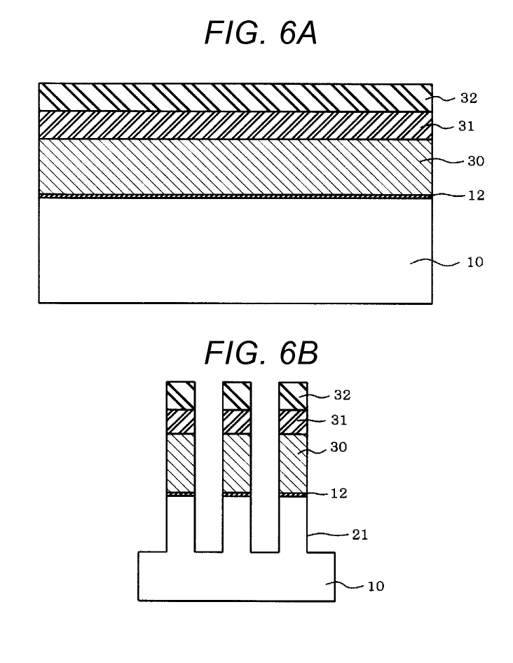

As shown in FIGS. 6A and 6B, dry etching is performed in an anisotropic condition using RIE by using the first silicon oxide film 32 patterned in the above-described step as a mask. Accordingly, the first polysilicon film 30 is patterned, and, subsequently, the gate oxide film 12 and the semiconductor substrate 10 are etched so as to form the element isolation grooves 21. The second polysilicon film 33 on the first silicon oxide film 32 is removed in the initial etching stage of this step.

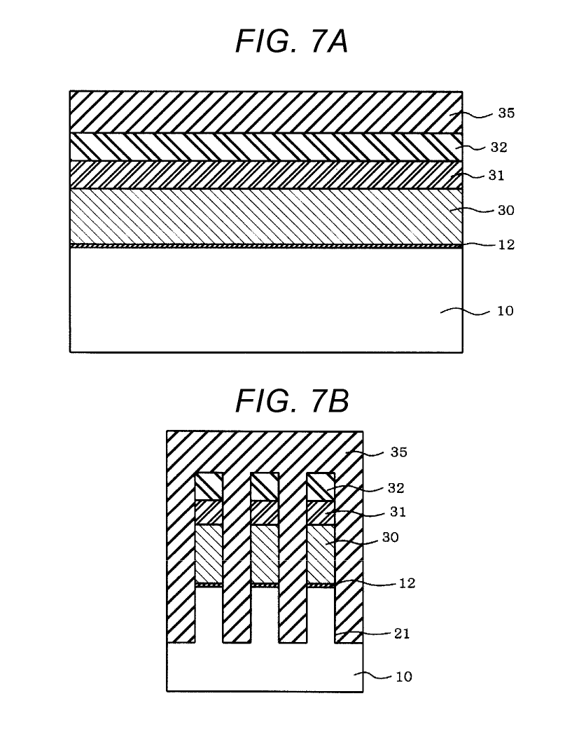

Next, as shown in FIGS. 7A and 7B, a second silicon oxide film 35 (the element isolation insulating film 22 formed in the subsequent steps) is formed over the entire surface of the semiconductor substrate so as to be embedded in the element isolation grooves 21. The second silicon oxide film 35 may be formed by forming a silicon oxide film, for example, using a CVD method, then coating a polysilazane solution using a spin coating method, and performing heat treatment thereon in a water vapor atmosphere.

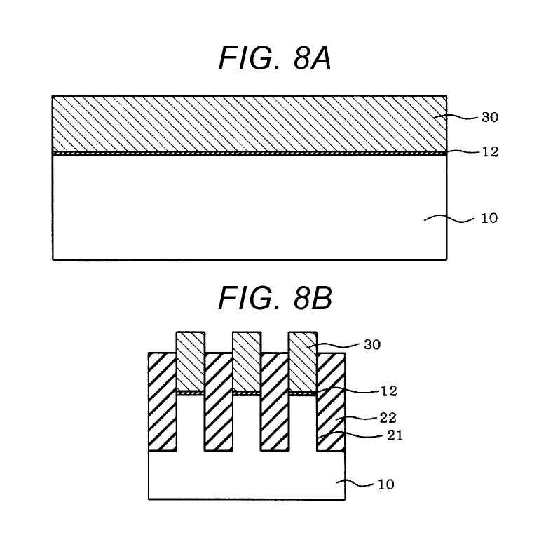

Next, as shown in FIGS. 8A and 8B, the second silicon oxide film 35 is polished using chemical mechanical polishing (CMP), and the polishing is stopped on the first silicon nitride film 31. Successively, the second silicon oxide film 35 is etched using RIE so as to be etched back, thereby setting an upper surface height of the second silicon oxide film 35 to a desired height lower than the upper surface of the first polysilicon film 30. Subsequently, the first silicon nitride film 31 is selectively removed through an etching process using, for example, phosphoric acid (hot phosphoric acid) which is heated to about 140° C. Through the above-described steps, the element isolation insulating film 22 which is embedded in the element isolation groove 21 is formed.

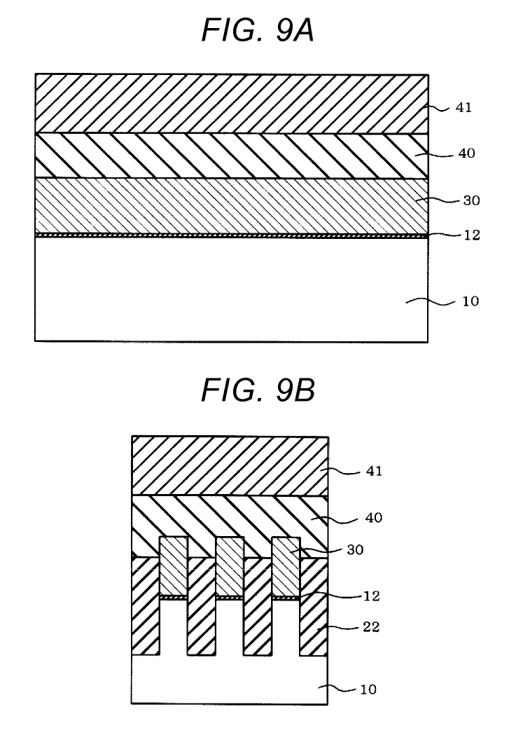

Next, as shown in FIGS. 9A and 9B, a first sacrificial film 40 and a third silicon oxide film 41 are sequentially formed. The first sacrificial film 40 may be formed by forming a silicon nitride film, for example, using a CVD method. The first sacrificial film 40 is formed with a predetermined film thickness so as to be embedded in the grooves between the adjacent first polysilicon films 30 and to cover the upper parts of the first polysilicon films 30. The third silicon oxide film 41 may be a silicon oxide film which is formed, for example, using a CVD method.

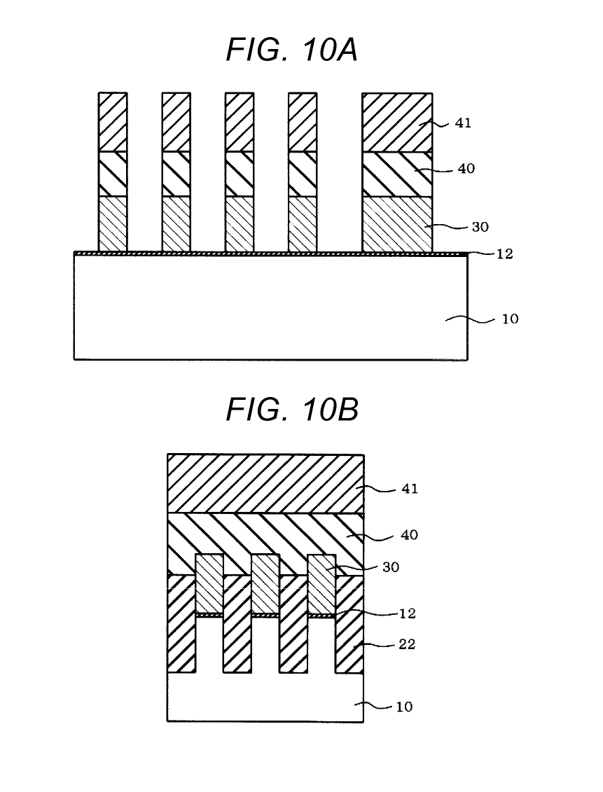

Next, as shown in FIGS. 10A and 10B, the third silicon oxide film 41, the first sacrificial film 40, and the first polysilicon film 30 are sequentially etched through a lithography method using RIE. Accordingly, columnar shapes are formed in which the first polysilicon film 30, the first sacrificial film 40, and the third silicon oxide film 41 are laminated.

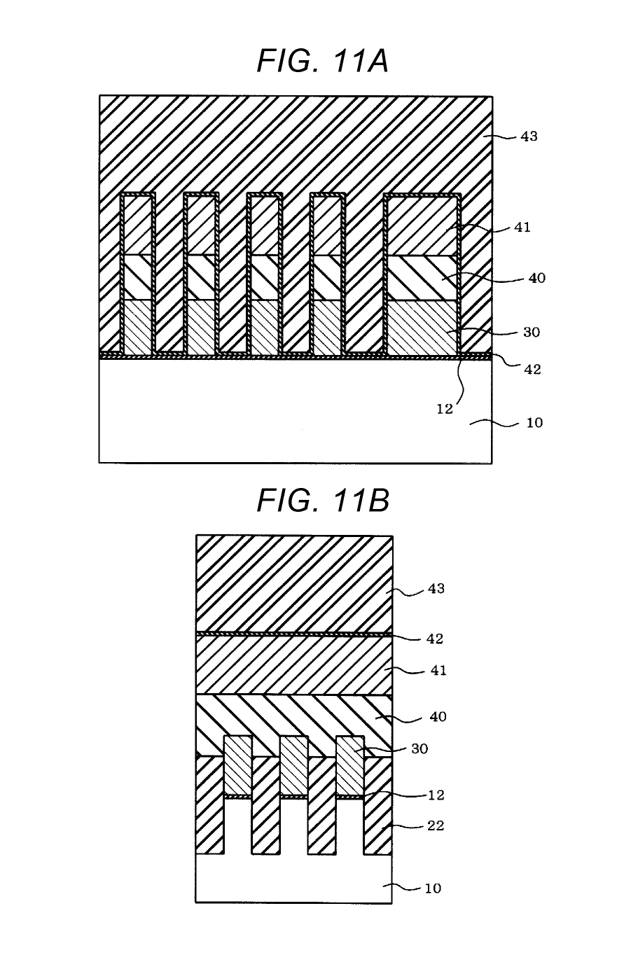

Next, as shown in FIGS. 11A and 11B, a liner film 42 is formed over the entire surface of the semiconductor substrate, and then an interlayer sacrificial film 43 is formed. The interlayer sacrificial film 43 is formed so as to be embedded in the groove portions between the columnar shapes and to cover the liner film 42. The liner film 42 may be a silicon oxide film which is formed, for example, using a CVD method. The interlayer sacrificial film 43 may be, for example, a silicon oxide film which is formed by coating a polysilazane solution using a spin coating method, and performing heat treatment thereon in a water vapor atmosphere. Alternatively, a silicon oxide film may be used which is formed using a plasma CVD method or a low pressure chemical vapor deposition (LPCVD) method.

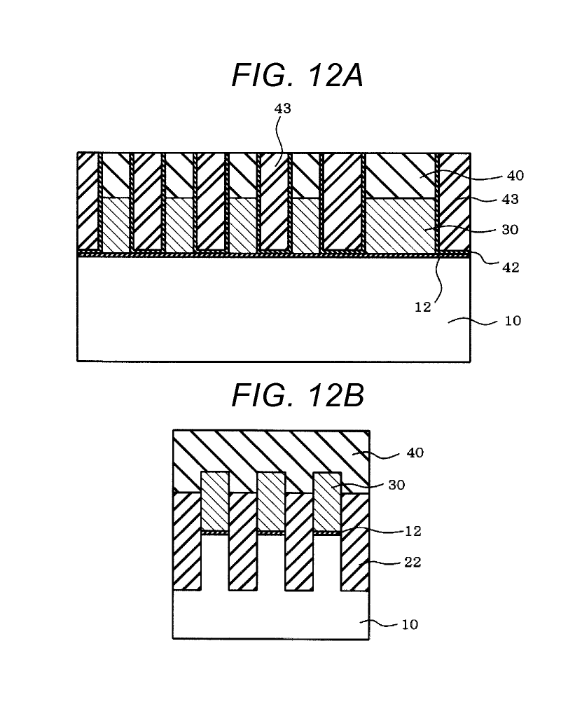

Next, as shown in FIGS. 12A and 12B, the interlayer sacrificial film 43, the liner film 42, and the third silicon oxide film 41 are polished by CMP, and the polishing is stopped at the upper surface of the first sacrificial film 40. Through this step, the entire surface is planarized at the upper surface height of the first sacrificial film 40. In addition, through this step, the upper surface of the first sacrificial film 40 is exposed. Further, the entire surface over the semiconductor substrate may be etched through isotropic dry etching using RIE, instead of the CMP. This etching is performed in a condition in which a selectivity for the interlayer sacrificial film 43, the liner film 42 and the third silicon oxide film 41 is low (low selectivity RIE).

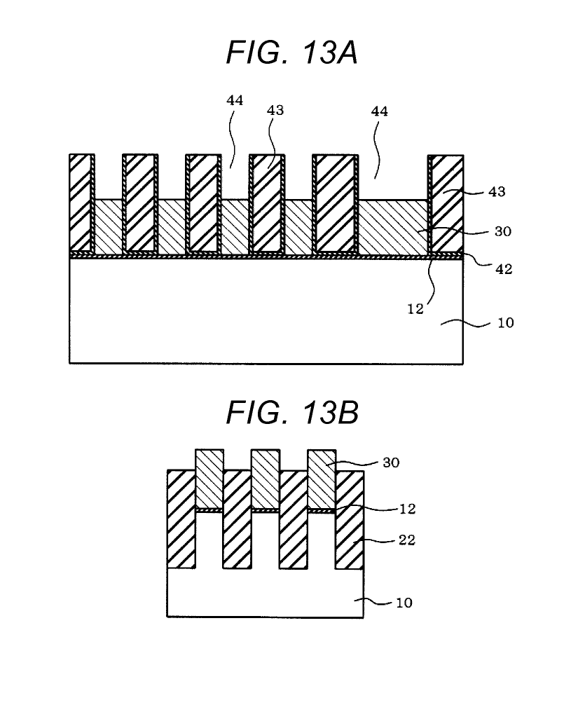

Next, as shown in FIGS. 13A and 13B, the first sacrificial film 40 is etched, for example, using hot phosphoric acid so as to be selectively removed. Through this step, the surface of the first polysilicon film 30 is exposed. In addition, through this step, the region from which the first sacrificial film 40 is removed becomes a groove 44 formed by the side surfaces of the interlayer sacrificial films 43 and the upper surface of the first polysilicon film 30.

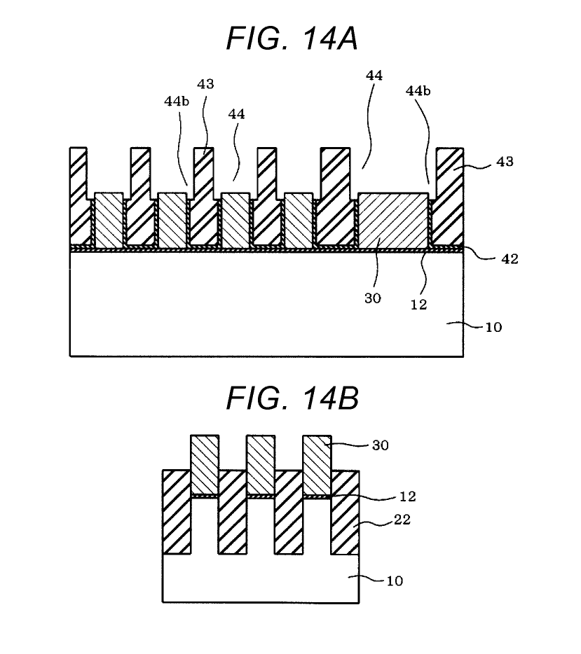

Next, as shown in FIGS. 14A and 14B, the liner film 42 which are exposed by the groove 44 and the interlayer sacrificial film 43 are etched back by for example, using a diluted hydrofluoric acid solution. The etching using the diluted hydrofluoric acid solution is isotropic, and thus the films are etched back by the substantially same film thickness in the longitudinal direction and transverse direction in FIGS. 14A and 14B. The first polysilicon film 30 is barely etched by the diluted hydrofluoric acid solution and is thus minimally etched back. This etching increases a transverse width (a width in the gate length direction) of the groove 44. In addition, the side surface around the upper surface of the first polysilicon film 30 is exposed. A gap 44b occurs in the side surface around the upper surface of the first polysilicon film between the side surface thereof and the interlayer sacrificial film 43. Further, the upper part of the element isolation insulating film 22 may also be removed.

The diluted hydrofluoric acid solution may be, for example, a buffered hydrofluoric acid solution in which a hydrofluoric acid aqueous solution (for example, 55 to 45% aqueous solution) and an ammonium fluoride solution are diluted at a content ratio of 1:30. A width of the groove 44 and a width and a depth of the gap 44b, that is, the etched-back amount of the interlayer sacrificial film 43 can be controlled by adjusting treatment time using the above-described diluted hydrofluoric acid solution.

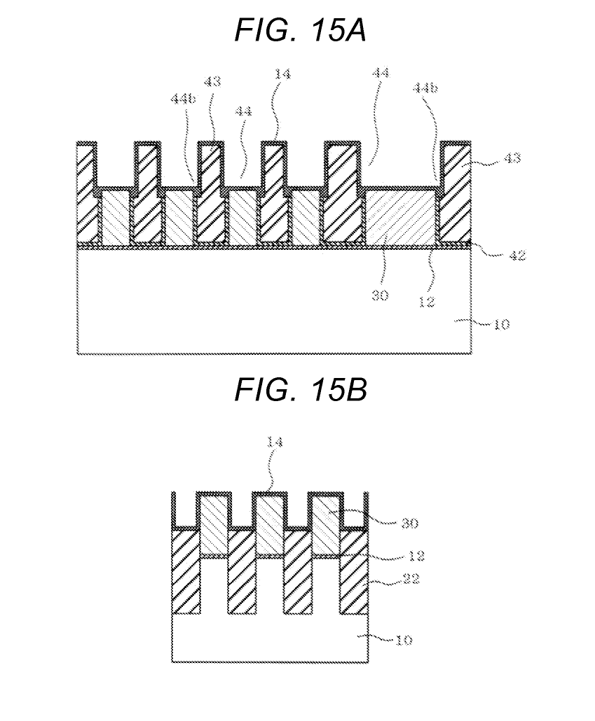

Next, as shown in FIGS. 15A and 15B, a first insulating film 14 is formed over the entire surface of the semiconductor substrate. The first insulating film 14 may be an ONO film which is formed, for example, using a CVD method.

If the film thickness of the first insulating film 14 is equal to or lower than a half of the width of the above-described gap 44b, as shown in FIG. 4A, the first insulating film 14 is formed along the interface of the gap 44b, and thus is not embedded in the gap 44b. On the other hand, if the film thickness of the first insulating film 14 is equal to or more than a half of the width of the above-described gap 44b, as shown in FIG. 4B, the first insulating film 14 is embedded in the gap 44b. For convenience, FIG. 15A shows a case where the first insulating film 14 is embedded in the gap 44b. In addition, the first insulating film 14 is used as an inter-electrode insulating film for insulating the floating gate electrode 13 and the control gate electrode 15 from each other in the memory cell gate electrode MG of the NAND type flash memory device according to the present embodiment.

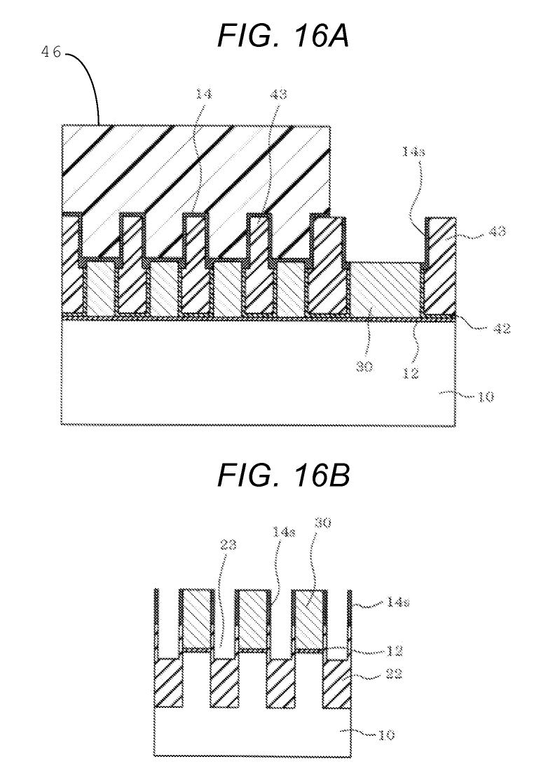

Next, as shown in FIGS. 16A and 16B, a resist mask 46 is formed using a lithography method. The resist mask 46 covers the region where the memory cell gate electrodes MG are formed. the resist mask 46 has an opening where the selection gate electrode SG is formed. Anisotropic dry etching using RIE is performed on the first insulating film 14 by using the resist mask 46 as a mask. Therefore, the first insulating film 14 on the interlayer sacrificial film 43 and the first polysilicon film 30 of the region which is not covered by the resist mask 46 is removed such that a first insulating film side wall 14s having a side wall shape is formed on the side surface of the interlayer sacrificial film 43.

Here, through this step, as shown in FIG. 16B, in the cross-section of the selection gate electrode SG along the gate width direction, the first insulating film 14 on the first polysilicon film 30 is removed, and the first insulating film side wall 14s having a side wall shape is formed on the side surface of the first polysilicon film 30. In addition, the time for the etching is set to be longer than the time when the film thickness of the first insulating film 14 is etched in the direction in which the floating gate electrode 13 and the control gate electrode 15 are laminated. Through this anisotropic dry etching, a groove 23 is formed in the central portion of the element isolation insulating film 22. The groove 23 have a shape that is defined by the first insulating film side wall 14s.

The element isolation insulating film 22 substantially remains on the side surface of the groove 23 and has the same film thickness as the first insulating film side wall 14s. The first polysilicon film 30, the gate oxide film 12 and the semiconductor substrate 10, and the groove 23 are separated from one another by the element isolation insulating film 22. The bottom surface of the groove 23 is located at a position lower than the lower surface of the gate oxide film. 12. A depth of the groove 23 can be controlled by adjusting the treatment time for the above-described anisotropic dry etching.

In the region masked by the resist mask 46, the first insulating film 14 is not etched but is present.

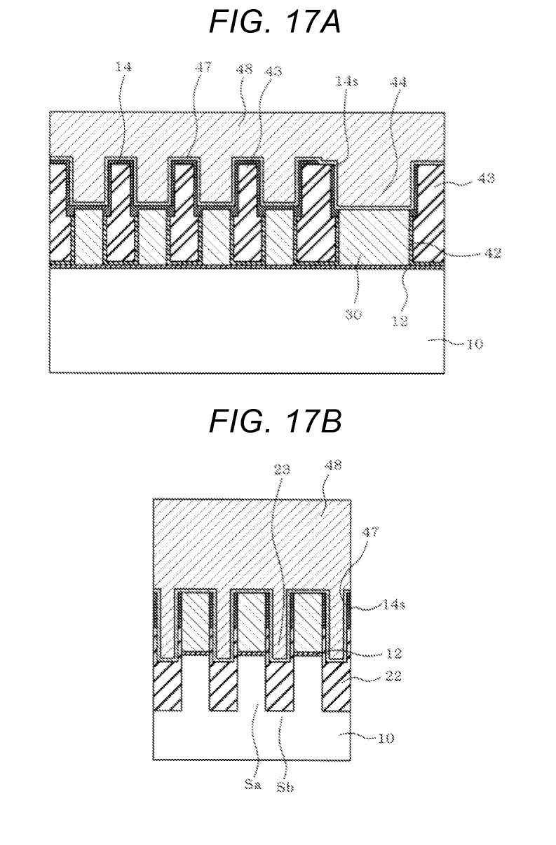

Next, the resist mask 46 is removed, and then a barrier metal 47 and a metal film 48 are formed as shown in FIGS. 17A and 17B. The barrier metal 47 may be tungsten nitride (WN) which is formed, for example, using a CVD method. The metal film. 48 may be tungsten (W) which is formed, for example, using a CVD method. The barrier metal 47 is in contact with the first polysilicon film 30 of the region where the selection gate electrode SG is formed. The barrier metal 47 is electrically connected to the first polysilicon film 30 in this portion. As shown in FIG. 17B, the barrier metal 47 and the metal film 48 fill the groove 23 formed in the element isolation insulating film 22.

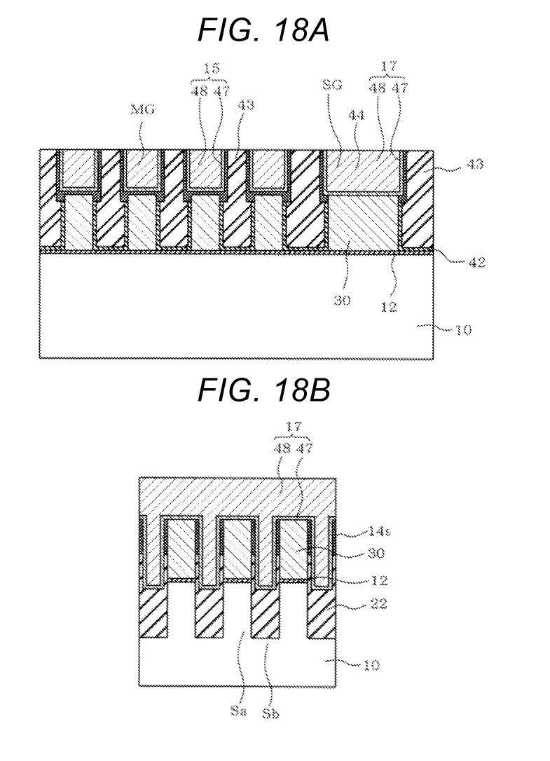

Next, as shown in FIGS. 18A and 18B, the metal film 48 and the barrier metal 47 are polished, for example, through a CMP method in which the interlayer sacrificial film 43 is used as a stopper, so as to be removed until the upper surface of the interlayer sacrificial film 43 is exposed. As a result, the metal film 48 and the barrier metal 47 are embedded in a groove 44 between the interlayer sacrificial films 43 and are thus processed in a wiring shape divided by the interlayer sacrificial film 43 along the gate length direction. Through this step, the control gate electrode 15 of the memory cell gate electrode MG and the upper electrode 17 of the selection gate electrode SG are formed.

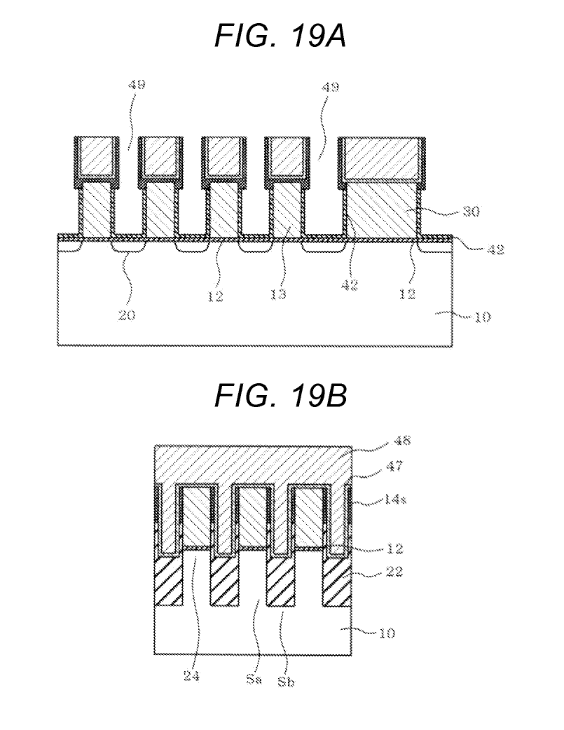

Next, as shown in FIGS. 19A and 19B, the interlayer sacrificial film. 43 is selectively removed, for example, using a diluted hydrofluoric acid solution or vapor-phase HF. Therefore, gaps 49 (air gaps AG described later) are formed between the memory cell gate electrodes MG and between the memory cell gate electrode MG and the selection gate electrode SG. Subsequently, for example, phosphorous is implanted using an ion implanting method, such that source drain regions 20 are formed in the semiconductor substrate 10 located on both sides of each of a plurality of memory cell gate electrodes MG and both sides of the selection gate electrode SG.

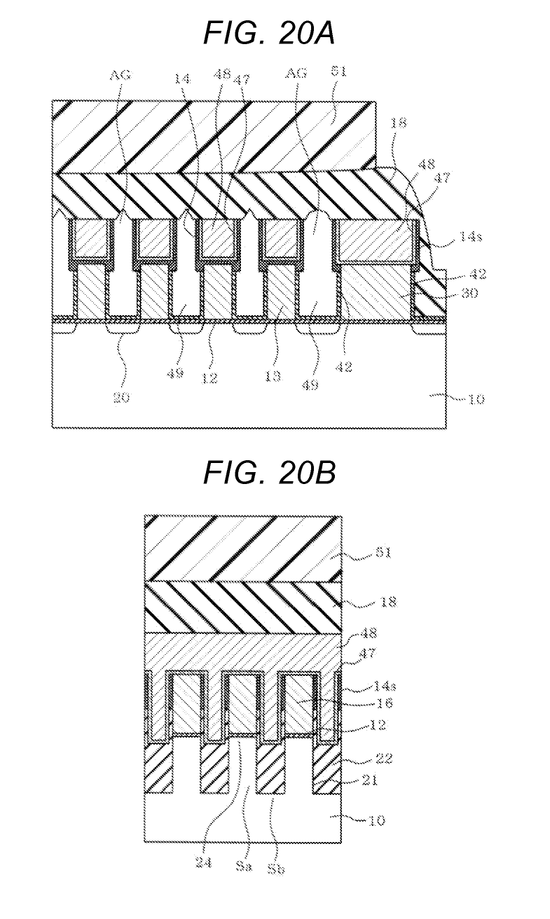

Next, as shown in FIGS. 20A and 20B, an insulating film 18 is formed over the entire surface of the semiconductor substrate. The insulating film 18 is formed by forming a silicon oxide film, for example, by a plasma CVD method in a condition in which coatability is low. Accordingly, the insulating film 18 can cover the upper parts of the gaps 49 like a lid in a state in which the gaps 49 are left. The insulating film 18 is not embedded in the gaps 49. The insulating film 18 is formed so as to cover the upper surfaces and the side surfaces of the memory cell gate electrodes MG and the selection gate electrode SG.

In addition, the width of the groove 44 is increased in the step described in FIGS. 14A and 14B, and thus the width of the control gate electrode 15 is increased. Accordingly, since a distance between the adjacent control gate electrodes 15 is reduced, the insulating film 18 is barely embedded between the memory cell gate electrodes MG and between the memory cell gate electrode MG and the selection gate electrode SG, and the air gap AG easily remains.

In this way, the gap 49 becomes the air gap AG. In other words, the insulating film 18 functions as a lid between the memory cell gate electrodes MG and between the memory cell gate electrode MG and the selection gate electrode SG, so as to form the air gap AG which is a closed space. Subsequently, a resist mask 51 which covers from the memory cell gate electrode MG forming region to the approximately central portion of the selection gate electrode SG is formed using a lithography method.

Next, referring back to FIGS. 3A and 3B, anisotropic dry etching is performed using the resist mask 51 as a mask, such that the side wall insulating film 19 is formed on the side surface of the selection gate electrode SG located on an opposite side to the memory cell gate electrode MG. Subsequently, the resist mask 51 is removed.

Through the above-described steps, the NAND type flash memory device 1 according to the present embodiment is formed.

As described above, in the present embodiment, the control gate electrode 15 of the memory cell gate electrode MG and the upper electrode 17 of the selection gate electrode SG are formed using a so-called damascene method. For this reason, processing of the metal film 48 used in the control gate electrode 15 and the upper electrode 17 is not performed through dry etching using a lithography method, and thus, for example, it is possible to prevent nonuniformity in a processed shape due to a grain size of tungsten used as the metal film 48.

In addition, when the control gate electrode 15, and the upper electrode 17 of the selection gate electrode SG are formed, a so-called damascene method is employed, and a so-called air gap AG structure is also realized. Therefore, a parasitic capacitance between the memory cell gate electrodes MG can be reduced by the air gap AG while improving uniformity in shapes of the control gate electrode 15 and the upper electrode 17.

Further, since the width of the groove 44 is increased through an etching process using a diluted hydrofluoric acid solution in FIGS. 14A and 14B, the cross-sectional areas of the control gate electrode 15 and the upper electrode 17 are increased which are formed so as to be embedded in the groove 44. Therefore, resistance values of the control gate electrode 15 and the upper electrode 17 are reduced. Furthermore, since the width of the bottom surface of the control gate electrode 15 is larger than the width of the upper surface of the floating gate electrode 13, a coupling ratio between the control gate electrode and the floating gate electrode of the memory cell gate electrode MG is improved by a wraparound electric field. Moreover, since the gap 44b is formed through an etching process using a diluted hydrofluoric acid solution in FIGS. 14A and 14B, if a part of the control gate electrode 15 is embedded therein, the control gate electrode 15 is formed so as to be opposed to the upper surface and a part of the side surface of the floating gate electrode 13. Accordingly, a coupling ratio in the memory cell gate electrode MG is further increased. From the above description, the control gate electrode 15 improves a coupling ratio between the floating gate electrodes 13, thereby providing a nonvolatile semiconductor memory device having good writing and erasure characteristics.

In addition, in the step of FIGS. 16A and 16B, the upper surface of the first polysilicon film 30 of the selection gate electrode SG is removed, and the planarized portion of the central part of the element isolation insulating film 22 in the groove 23 is lower than the lower surface of the gate oxide film 12. As a result, a transistor with a fin structure can be formed while connecting the control gate electrode 15 of the selection gate transistor STS to the floating gate electrode 13 thereof, without increasing the number of manufacturing steps.

### Second Embodiment

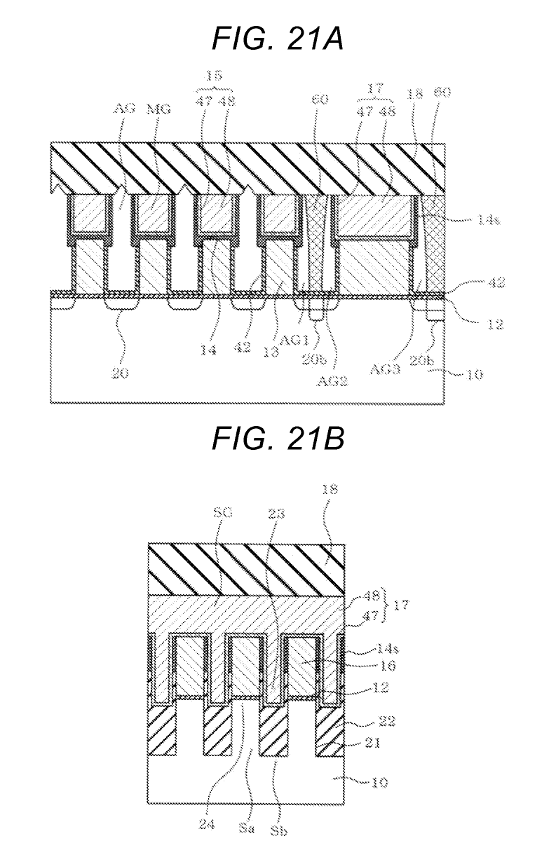

Next, a configuration according to the second embodiment will be described with reference to FIGS. 21A to 34B.

FIGS. 21A and 21B are diagrams schematically illustrating an example of a structure of a NAND type flash memory device according to the second embodiment. FIG. 21A is a diagram schematically illustrating an example of a cross-section taken along the line AA of FIG. 2. FIG. 21B is a diagram schematically illustrating an example of a cross-section taken along the line BB of FIG. 2.

In FIGS. 21A and 21B, differences between the NAND type flash memory device according to the second embodiment and the NAND type flash memory device according to the first embodiment are as follows. An air gap AG is formed between the memory cell gate electrodes MG, and additionally an air gap AG1 is formed on the side surface of the memory cell gate electrode MG which is adjacent to the selection gate electrode SG, and an air gap AG2 is formed on the side surface of the selection gate electrode SG opposed to the memory cell gate electrode MG. There is also an interlayer insulating film 60 that partition the air gaps AG1 and AG2. In addition, an air gap AG3 is also formed on the side surface of the selection gate electrode SG opposite to the side which is adjacent to the memory cell gate electrode MG. In other words, the air gaps AG2 and AG3 are formed on both side surfaces of the selection gate electrode SG.

The other configurations are substantially the same as in the first embodiment.

With the above configuration, the present embodiment achieves the same effects as the first embodiment.

In addition, the following effects can be achieved as effects unique to the present embodiment. If the selection gate electrode SG is a selection gate electrode SG on the source line SL side, as shown in FIG. 2, the control line SGS (the selection gate electrode SG) and the source line SL extend adjacently in the X direction, and are arranged in parallel to each other. Therefore, with the above-described configuration, the air gap AG3 is formed on the side wall of the selection gate electrode SG, and thus an interwire capacitance between the selection gate electrode SG and the source line SL is reduced. As a result, a high-speed operation of the selection gate transistor STS can be achieved.

Manufacturing Method

Hereinafter, a description will be made of an example of a manufacturing method of the nonvolatile semiconductor memory device according to the present embodiment.

First, the steps described in FIGS. 5A to 8B in the first embodiment are performed so as to produce the state shown in FIGS. 8A and 8B.

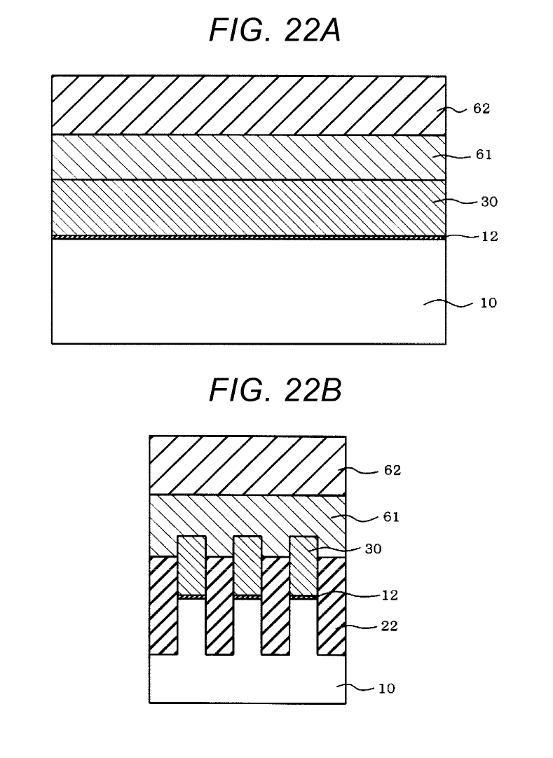

Next, as shown in FIGS. 22A and 22B, a second sacrificial layer 61 and a fourth silicon oxide film 62 are sequentially formed. The second sacrificial layer 61 may be SiGe which is formed, for example, using a CVD method. The second sacrificial layer 61 is formed with a predetermined film thickness so as to be embedded in the grooves between the adjacent first polysilicon films 30 and to cover the upper parts of the first polysilicon films 30. The fourth silicon oxide film 62 may be a boron silicate glass (BSG) film which is formed while doping boron by using tetraethyl orthosilicate (TEOS, Si(OC₂H₅)₄), for example, through a CVD method.

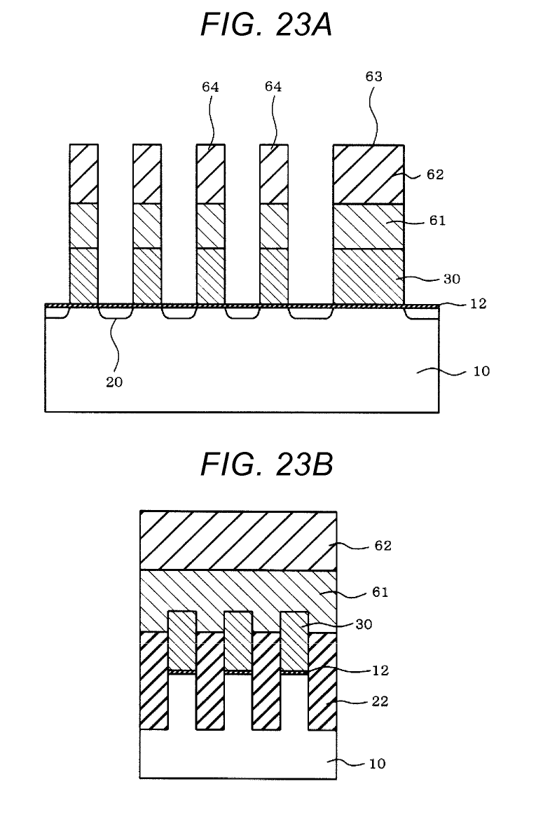

Next, as shown in FIGS. 23A and 23B, the fourth silicon oxide film 62, the second sacrificial layer 61, and the first polysilicon film 30 are sequentially etched through anisotropic dry etching using a lithography method and RIE. Accordingly, columnar shapes are formed in which the first polysilicon film 30, the second sacrificial layer 61, and the fourth silicon oxide film 62 are laminated. The columnar shape 63 of the forming region of the selection gate electrode SG and the columnar shapes 64 of the forming region of the memory cell gate electrodes MG are formed as the columnar shapes.

Next, for example, phosphorous is ion-implanted into the semiconductor substrate 10 located on both sides of the columnar shape 63 and the columnar shapes 64 as an impurity through an ion implanting method. Here, the regions into which the impurity is implanted finally become source drain regions 20 (for convenience, indicated by the source drain regions 20 in FIG. 23A) of transistors having the memory cell gate electrode MG and the selection gate electrode SG as gate electrodes.

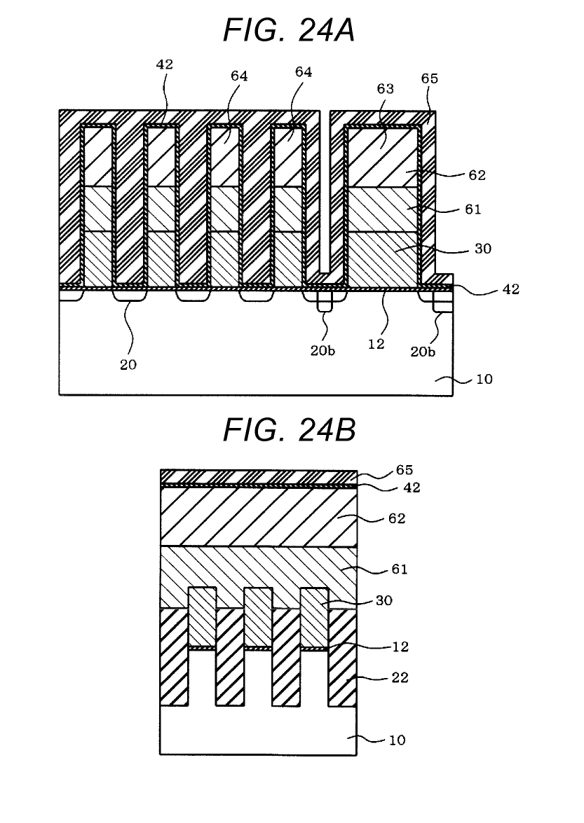

Next, as shown in FIGS. 24A and 24B, a liner film 42 is formed over the entire surface of the semiconductor substrate, and then a third sacrificial film 65 is formed. The liner film 42 may be a silicon oxide film which is formed, for example, using a CVD method. The third sacrificial film 65 may be a silicon nitride film which is formed, for example, using a CVD method. The third sacrificial film 65 is formed with a film thickness of being embedded in the groove portion between the columnar shapes 64 and of not being embedded in the groove portion between the columnar shape 63 and 64.

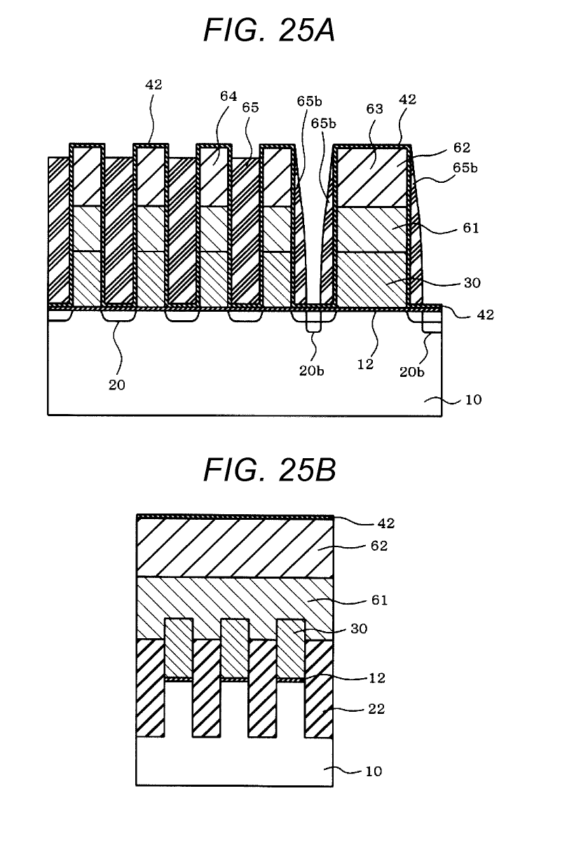

Next, as shown in FIGS. 25A and 25B, the third sacrificial film 65 is etched back by anisotropic dry etching using RIE, and thus a side wall 65b is formed by the third sacrificial film 65 on both side surfaces of the columnar shape 63. In addition, the side wall 65b is formed on the side surface of the columnar shape 64 which is opposed to the columnar shape 63. The third sacrificial film 65 is embedded between the columnar shapes 64. Through this step, the liner film 42 on the columnar shape 63 and the columnar shapes 64 are exposed. Next, ion implanting is performed so as to implant an impurity into the semiconductor substrate 10 adjacent to the side wall 65b. For example, arsenic is implanted as the impurity, so as to form a high-concentration impurity region 20b.

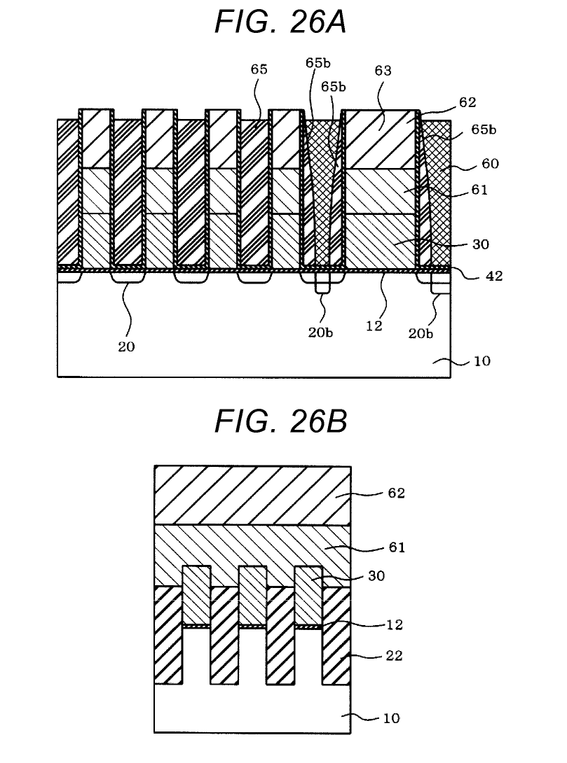

Next, as shown in FIGS. 26A and 26B, an interlayer insulating film 60 is formed over the entire surface of the semiconductor substrate, and then the interlayer insulating film 60 is formed between the side walls 65b of the columnar shape 63 and the columnar shape 64, and on the side surface of the side wall 65b by a CMP method in which the fourth silicon oxide film 62 is used as a stopper. The interlayer insulating film 60 may be a silicon oxide film which is formed, for example, using a CVD method. In addition, in FIGS. 26A and 26B, the upper surface of the interlayer insulating film 60 is located at a slightly lower position than the upper surface of the fourth silicon film, but the upper surface of the interlayer insulating film 60 may be substantially the same as the upper surface of the fourth silicon film depending on a condition of a CMP method. Further, through this step, the liner film 42 on the columnar shape 63 and the columnar shapes 64 is removed so as to expose the upper surface of the fourth silicon oxide film 62.

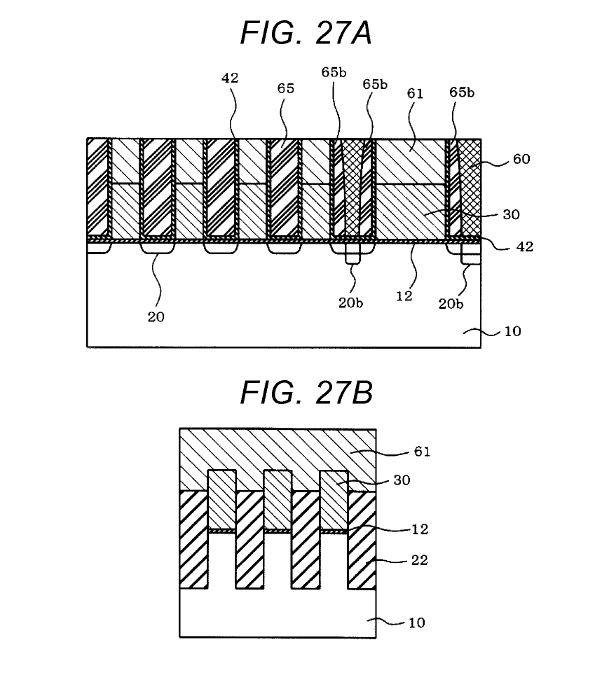

Next, as shown in FIGS. 27A and 27B, etching is performed over the entire surface of the semiconductor substrate by isotropic dry etching using RIE. This etching is performed in a condition in which a selectivity between the silicon oxide film and the silicon nitride film is low (low selectivity RIE).

This etching stops when the surface of the second sacrificial layer 61 is exposed. Through this etching, the fourth silicon oxide film 62, the interlayer insulating film 60, the liner film 42, and the third sacrificial film 65 are isotropically etched and are removed so as to have surfaces thereof which are planarized at the upper surface height of the second sacrificial layer 61.

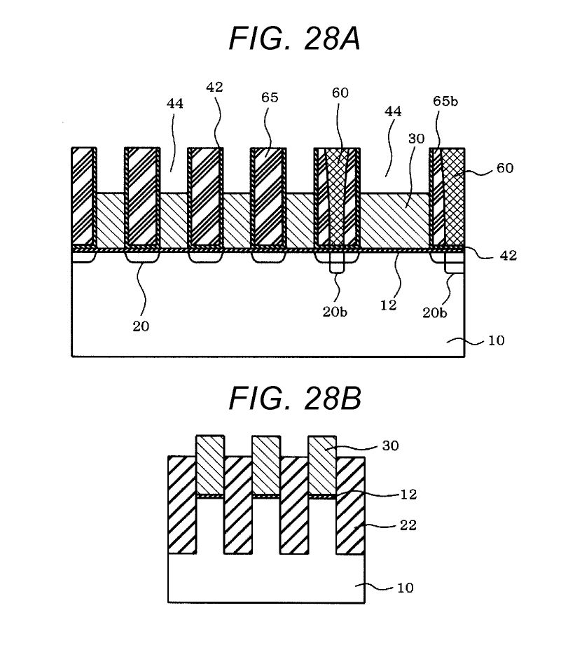

Successively, as shown in FIGS. 28A and 28B, the second sacrificial layer 61 is selectively removed. The second sacrificial layer 61 may be removed, for example, using an ammonia-hydrogen peroxide solution. Through this step, the second sacrificial layer 61 is selectively removed from the location where the second sacrificial layer is embedded so as to form grooves 44.

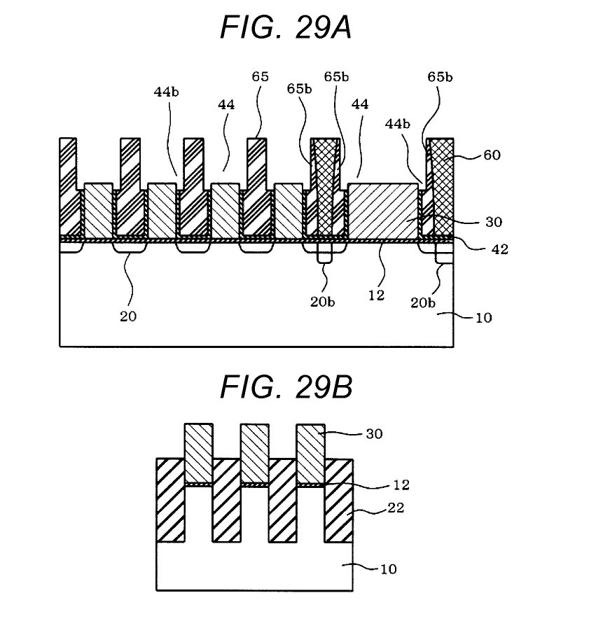

Next, as shown in FIGS. 29A and 29B, dry etching is performed in an isotropic condition so as to increase the widths of the grooves 44. This etching is performed in a condition in which a selectivity between the silicon oxide film and the silicon nitride film is low. Therefore, the liner film 42 exposed by the groove 44, and the third sacrificial film 65 and the side wall 65b located outside the groove 44 are isotropically etched and substantially the same thickness of the films (the liner film 42, the third sacrificial film 65 and the side wall 65b) disposed in each groove 44 is removed in the longitudinal direction and the transverse direction in FIGS. 29A and 29B. The first polysilicon film 30 is barely etched by the diluted hydrofluoric acid solution and is thus scarcely retreated. This etching increases a transverse width (a width in the gate length direction) of the groove 44.

In addition, the side surface around the upper surface of the first polysilicon film 30 is exposed. A gap 44b results in the side surface around the upper surface of the first polysilicon film 30 between the side surface thereof and the third sacrificial film 65. A width of the groove 44 and a width and a depth of the gap 44b, that is, an etch-back amount of the liner film 42, the third sacrificial film 65 and the side wall 65b can be controlled by adjusting the treatment time for the above-described dry etching.

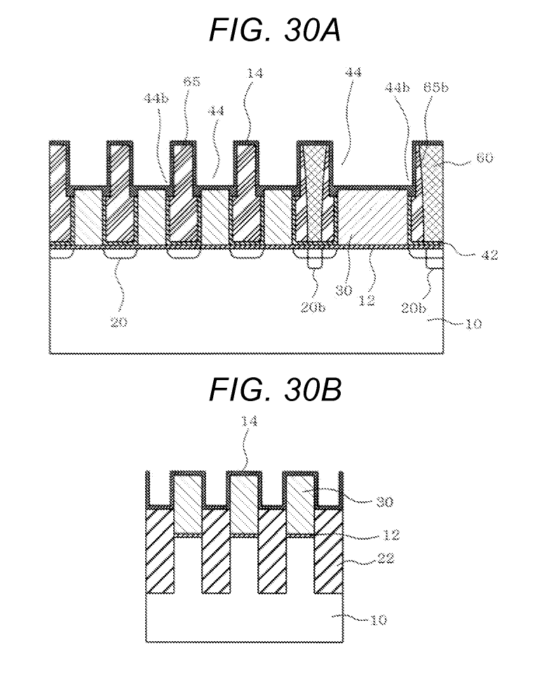

Next, as shown in FIGS. 30A and 30B, a first insulating film 14 is formed over the entire surface of the semiconductor substrate. The first insulating film 14 may be an ONO film which is formed, for example, using a CVD method.

A relationship between a film thickness of the first insulating film 14 and a width of the gap 44b is the same as described with reference to FIGS. 4A and 4B in the first embodiment. For convenience, FIG. 30A shows a case where the first insulating film 14 is embedded in the gap 44b.

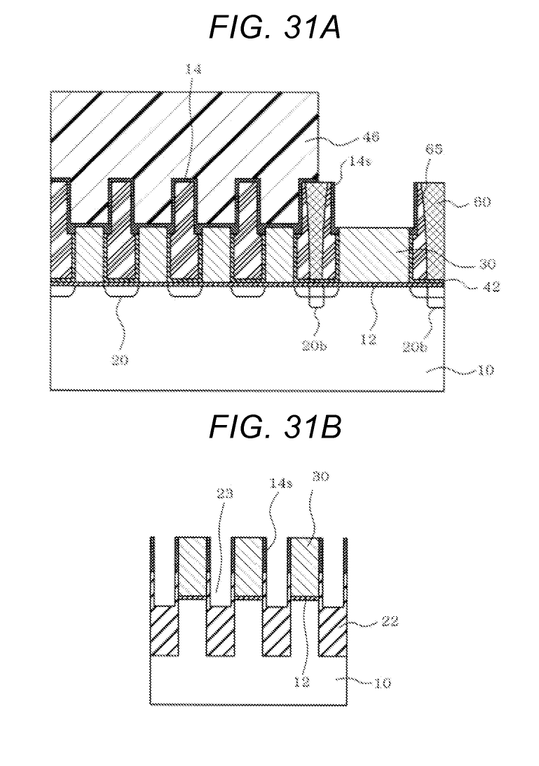

Next, as shown in FIGS. 31A and 31B, a resist mask 46 is formed using a lithography method. The resist mask 46 covers the region where the memory cell gate electrodes MG are formed.

The resist mask 46 has an opening where the selection gate electrode SG is formed. Dry etching is performed on the first insulating film 14 by using the resist mask 46 as a mask in an anisotropic condition using RIE. Therefore, the first insulating film 14 on the interlayer insulating film 60, the third sacrificial film 65, and the first polysilicon film 30 of the region in which the selection gate electrode SG is formed is removed such that a first insulating film side wall 14s having a side wall shape is formed on the side surface of the third sacrificial film 65.

In addition, as shown in FIG. 31B, through this step, the first insulating film 14 on the first polysilicon film 30 is removed such that the first insulating film side wall 14s having a side wall shape is formed on the side surface of the first polysilicon film 30. Further, a groove 23 with a predetermined depth is formed in the central portion of the element isolation insulating film 22 having a shape defined by the first insulating film side wall 14s. The element isolation insulating film 22 substantially remains on the side surface of the groove 23 and has the same film thickness as the first insulating film side wall 14s. The first polysilicon film 30, the gate oxide film. 12 and the semiconductor substrate 10, and the groove 23 are separated from one another by the element isolation insulating film 22. A depth of the groove 23 can be controlled by adjusting the treatment time for the above-described etching. In the region masked by the resist mask 46, the first insulating film 14 is not etched but is present.

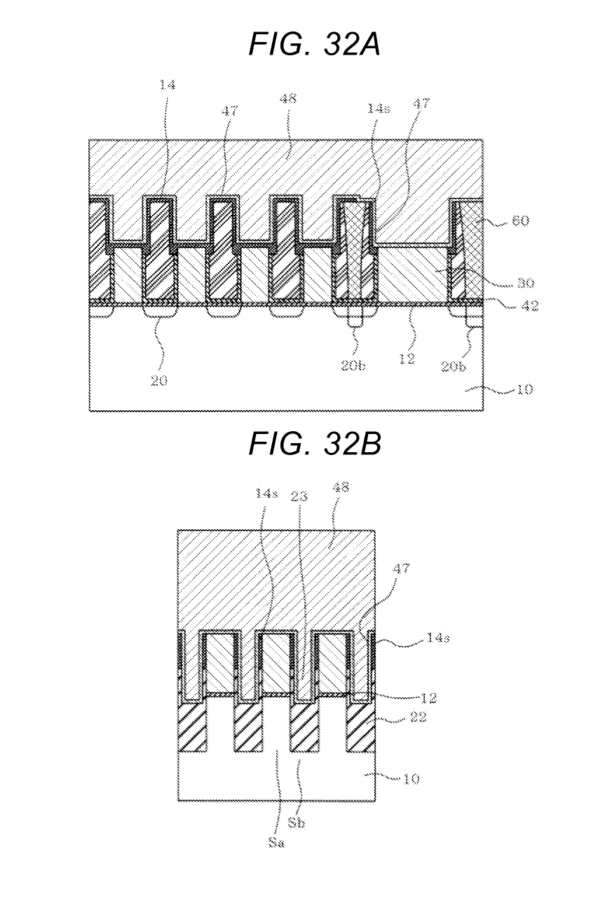

Next, the resist mask 46 is removed, and then a barrier metal 47 and a metal film 48 are formed as shown in FIGS. 32A and 32B. The barrier metal 47 may be tungsten nitride which is formed, for example, using a CVD method. The metal film 48 may be tungsten which is formed, for example, using a CVD method. The barrier metal 47 is insulated from the first polysilicon film 30 by the first insulating film 14 in the region where the memory cell gate electrode MG is formed. The barrier metal 47 is in contact with the first polysilicon film 30 in the region where the selection gate electrode SG is formed. As shown in FIG. 32B, the barrier metal 47 and the metal film 48 fill the groove 23 formed in the element isolation insulating film 22.

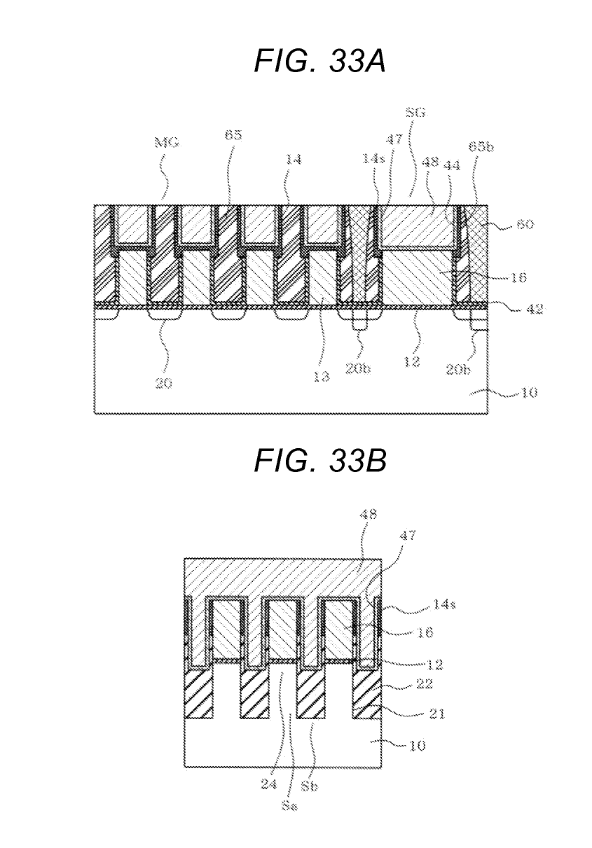

Next, as shown in FIGS. 33A and 33B, the metal film 48 and the barrier metal 47 are polished, for example, through a CMP method in which the third sacrificial film 65 or the interlayer insulating film 60 is used as a stopper, so as to be removed until the upper surface of the third sacrificial film 65 is exposed. As a result, the metal film 48 and the barrier metal 47 are embedded in grooves 44 between the third sacrificial films 65 and between the side walls 65b and are thus processed in a wiring shape divided by the third sacrificial film. 65 and the side walls 65b. Through this step, the memory cell gate electrodes MG and the selection gate electrode SG are formed. In addition, the upper surfaces of the third sacrificial film 65 and the side wall 65b are exposed.

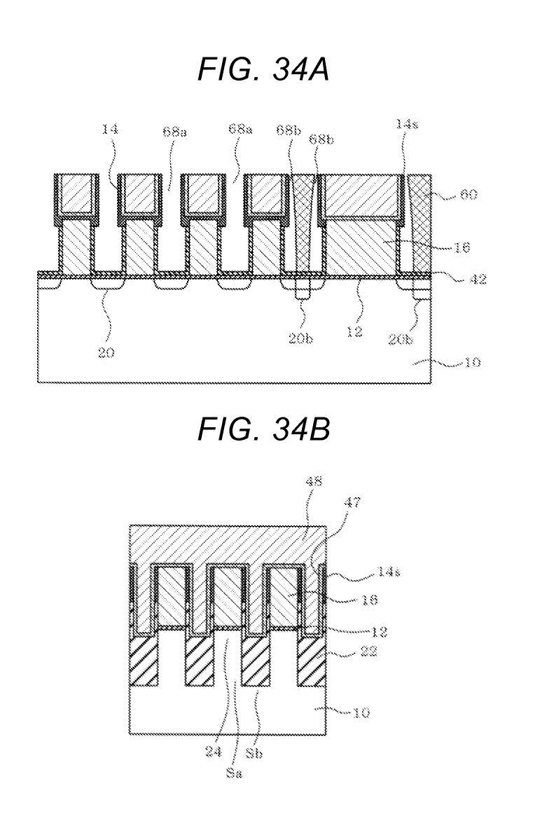

Next, as shown in FIGS. 34A and 34B, the third sacrificial film 65 and the side wall 65b are selectively removed, for example, using hot phosphoric acid. Accordingly, the third sacrificial films 65 and the side walls 65b are removed from the locations where the third sacrificial films and the side walls are embedded, so as to leave cavities, thereby forming gaps 68a and gaps 68b.

The gaps 68a indicate spaces provided between the memory cell gate electrodes MG and are formed as cavities by removing the third sacrificial film 65 from the locations in which the third sacrificial film is embedded. The gaps 68b indicate spaces having a side wall shape, formed on both side walls of the selection gate electrode SG, and the side wall of the memory cell gate electrode MG on the selection gate electrode SG side, and are formed as cavities by removing the side walls 65b from the locations in which the side walls are embedded. The gap 68b is formed between the selection gate electrode SG and the interlayer insulating film 60. The gap 68a becomes an air gap AG in the subsequent steps, and the gaps 68b become air gaps AG1, AG2 and AG3 in the subsequent steps.

Next, as shown in FIGS. 21A and 21B, an insulating film 18 is formed over the entire surface of the semiconductor substrate. The insulating film 18 is formed by forming a silicon oxide film, for example, through a plasma CVD method in a condition in which coatability is low.

Accordingly, the insulating film 18 can cover the upper parts of the gaps 68a and the gaps 68b like a lid in a state in which the gaps 68a and the gaps 68b are left. The insulating film 18 is not embedded in the gaps 68a and the gaps 68b. The insulating film 18 is formed so as to cover all the upper surfaces of the interlayer insulating film 60, the memory cell gate electrodes MG, and the selection gate electrode SG.

In addition, the width of the groove 44 is increased in the step described in FIGS. 29A and 29B, and thus the width of the control gate electrode 15 is increased. Accordingly, since a distance between the adjacent control gate electrodes 15 is reduced, the plasma insulating film 18 is barely embedded in the gaps 68a.

In this way, the gaps 68a between the memory cell gate electrodes MG and the gaps 68b between the memory cell gate electrode MG and the side wall of the selection gate electrode SG are closed by the insulating film 18 so as to form air gaps AG, AG1, AG2 and AG3.

Through the above-described steps, the NAND type flash memory device 1 according to the present embodiment is formed.

As described above, the present embodiment achieves the same effects as the first embodiment.

Further, in the present embodiment, since the air gaps AG are formed on both side walls of the selection gate electrode SG, an interwire capacitance between the selection gate electrode SG and the source line SL is reduced, and thus an effect of being capable of contributing to a high-speed operation of the selection gate transistor STS can be achieved.

### Other Embodiments

In addition to the above-described embodiments, the following modifications can be made.

Although an ONO film is used as the first insulating film as an example in the above-described embodiment, a nitride-oxide-nitride-oxide-nitride (NONON) film or an insulating film with a high permittivity may be used.

Although SiGe is used as the second sacrificial film 61 as an example in the embodiment, for example, amorphous carbon may be used instead of SiGe. In this case, the amorphous carbon may be selectively removed using oxygen plasma asking.

In addition, although the embodiments are applied to a NAND type flash memory device as an example, the embodiments may be applied to a nonvolatile semiconductor memory device such as a NOR type flash memory device or EEPROM.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a semiconductor substrate; and
a memory cell array having memory cells arranged along a first direction that is transverse to a second direction in which word lines for the memory cells extend, each memory cell including a charge accumulation layer provided over the semiconductor substrate, a control gate electrode provided over the charge accumulation layer, and an inter insulating film provided between the charge accumulation layer and the control gate electrode,
wherein the inter insulating film is wider along the first direction than the charge accumulation layer and covers opposing side surfaces of an upper portion of the charge accumulation layer in the first direction.

2. The device according to claim 1, wherein the control gate electrode is made of a barrier metal and a metal material.

3. The device according to claim 1, wherein the control gate electrode is wider along the first direction than the charge accumulation layer.

4. The device according to claim 1, wherein a part of the control gate electrode is opposed to the upper portion of the charge accumulation layer at a position lower than an upper surface of the charge accumulation layer.

5. The device according to claim 1, wherein a gap is formed between the memory cells.

6. The device according to claim 1, further comprising:
a selection gate transistor that is adjacent to one of the memory cells and includes a selection gate electrode provided over the semiconductor substrate and over a channel region provided in the semiconductor substrate; and
an element isolation region in which an insulating film is formed on both sides of the channel region.

7. The device according to claim 6, further comprising:
a groove formed in the insulating film that is filled with the selection gate electrode, the groove extending in the second direction.

8. The device according to claim 6, wherein a first gap is formed between the memory cells and a second gap is formed between the selection gate transistor and the memory cell that is adjacent thereto.

9. The device according to claim 8, wherein the second gap is partitioned by a first insulating film.

10. The device according to claim 8, wherein a third gap is formed on a side of the selection gate transistor that is opposite to the memory cells.

11. A nonvolatile semiconductor memory device comprising:
semiconductor substrate; and
a memory cell array having memory cells arranged along a first direction that is transverse to a second direction in which word lines for the memory cells extend, memory cell including a charge accumulation layer provided over the semiconductor substrate, a control gate electrode provided over the charge accumulation layer, and an inter insulating film provided at an interface between the charge accumulation layer and the control gate electrode,
wherein the control gate electrode is wider along first direction than the charge accumulation layer and extends below the interface to be opposed to an upper portion of the charge accumulation layer at a position lower than an upper surface of the charge accumulation layer.

12. The nonvolatile semiconductor memory device according to claim 11, wherein the inter insulating film extends below the interface to be interposed between the control gate electrode and the upper portion of the charge accumulation layer.

13. The nonvolatile semiconductor memory device according to claim 12, wherein the inter insulating film covers an outer periphery of the control gate electrode that extends below the interface.

14. The device according to claim 13, wherein the control gate electrode is made of a barrier metal and a metal material.

15. The device according to claim 11, further comprising:
a selection gate transistor that is adjacent to one of the memory cells and includes a selection gate electrode provided over the semiconductor substrate and over a channel region provided in the semiconductor substrate; and
an element isolation region in which an insulating film is formed on both sides of the channel region.

16. The device according to claim 15, further comprising:
a groove formed in the insulating film that is filled with selection gate electrode, the groove extending in the second direction.

17. The device according to claim 15, wherein a first gap is formed between the memory cells and a second gap is formed between the selection gate transistor and the memory cell that is adjacent thereto.

18. The device according to claim 17, wherein a third gap is formed on a side of the selection gate transistor that is opposite to the memory cells.

19. A method of manufacturing a nonvolatile semiconductor memory device, comprising:
sequentially forming a first sacrificial film and a first insulating film on a polysilicon film which is formed on a semiconductor substrate;
forming a first groove by sequentially etching the first insulating film, the first sacrificial film, and the polysilicon film;
embedding an element isolation insulating film in the first groove;
forming a second groove by etching the first insulating film, the first sacrificial film, and the polysilicon film;
embedding a second sacrificial film in the second groove;
removing the first sacrificial film and then removing a part of the second sacrificial film, so as to form a third groove;
embedding a metal material in the third groove;
selectively removing a side wall formed by the second sacrificial film so as to form a gap between the polysilicon films; and
forming a second insulating film over the semiconductor substrate without being embedded in the gap.

20. The method according to claim 19, wherein the metal material embedded in the third groove extends below an upper surface of the polysilicon film.
